(19) United States
(12) Patent Application Publication
(10) Pub. No.: US 2021/0408966 A1
(43) Pub. Date: Dec. 30, 2021

(54) ADVANCED QUANTUM POWER COLLECTOR

(71) Applicant: Quantum Grid Labs Limited, London (GB)

(72) Inventors: Randolph Allen ST JAMES, San Leandro, CA (US); Ming Hwa LEE, Fremont, CA (US)

(73) Assignee: Quantum Grid Labs Limited, London (GB)

(21) Appl. No.: 17/467,786

(22) Filed: Sep. 7, 2021

Related U.S. Application Data
(63) Continuation-in-part of application No. 16/632,220, filed on Jan. 17, 2020.

(30) Foreign Application Priority Data
Jul. 18, 2017 (GB) 1711546.0

(51) Int. Cl. H02S 40/36; H01L 51/42; H01L 51/44; H02S 40/38

(52) U.S. Cl. CPC H02S 40/36; H02S 40/38; H01L 51/442; H01L 51/426

(57) ABSTRACT

A photovoltaic collector includes a photovoltaic cell including a first conduction layer, a second conduction layer, and a photovoltaic layer absorbing incident light and generating electric current. The photovoltaic layer is electrically connected to the first conduction layer on a first side of the photovoltaic layer and to the second conduction layer on a second side opposite to the first side. The first conduction layer is an ultrastatic conducting layer being made using ultrasonic spray technology. The photovoltaic collector further includes a plurality of connection units disposed along on an outer peripheral edge of the photovoltaic collector. Each connection unit is adapted to connect with an adjacent connection unit of an adjacent photovoltaic collector to tessellate and electrically interconnect and interlock the photovoltaic collector with a plurality of adjacent photovoltaic collectors without requiring additional cable wires.

### CROSS REFERENCE TO RELATED APPLICATIONS

This application is a continuation-in-part of U.S. patent application Ser. No. 16/632,220, filed Jan. 17, 2020, titled “POWER COLLECTOR,” which claims the benefit of and priority to PCT/GB2018/052022, filed Jul. 17, 2018, titled, “POWER COLLECTOR,” which claims priority to GB application, GB1711546.0, filed Jul. 18, 2017, titled, “POWER COLLECTOR,” all of which are hereby incorporated by reference as if reproduced in their entirety.

### TECHNICAL FIELD

The present disclosure generally relates to power collectors and, more specifically, to advanced quantum power collectors capable of converting visible light energy and/or infrared energy into electricity.

### BACKGROUND

Typical photovoltaic cells are implemented using bulk semiconductor materials, such as silicon, to generate electric power. The generation of electricity of such bulk semiconductor materials relies on absorbing photons with energy greater than the bandgaps of the bulk semiconductor material, which corresponds to energies greater than the electromagnetic energy in the infrared spectrum. Consequently, photovoltaic cells made from conventional bulk semiconductor materials neither absorb nor generate electricity from infrared energy. Notably, half of the solar energy reaching the Earth has wavelengths in the infrared spectrum, which means that conventional photovoltaic cells neglect half of the solar energy reaching the Earth. The challenge is to develop a photovoltaic cell to capture electromagnetic energy within the infrared spectrum.

### SUMMARY

The following presents a simplified summary of one or more examples in order to provide a basic understanding of such examples. This summary is not an extensive overview of all contemplated examples and is intended to neither identify key or critical elements of all examples nor delineate the scope of any or all examples. Its purpose is to present some concepts of one or more examples in a simplified form as a prelude to the more detailed description that is presented below.

In one embodiment, a photovoltaic collector is provided which includes: a photovoltaic cell configured to absorb incident light and generate electric current; a power collar disposed along a periphery of the photovoltaic cell, the power collar electrically coupled to at least one conduction layer of the photovoltaic cell; and a connection unit electrically connected to the power collar, the connection unit including: a first connector electrically connected to a positive terminal of the power collar; and a second connector electrically connected to a negative terminal of the power collar; where the first and second connectors are disposed at an outer peripheral edge of the photovoltaic collector, and where the first and second connectors are configured to interconnect the photovoltaic collector with a first adjacent photovoltaic collector.

In another embodiment, the photovoltaic collector further includes an energy cell disposed along the periphery of the photovoltaic cell, and wherein the power collar is electrically connected to the energy cell and is configured to direct charged carriers to the energy cell. The connection unit is electrically connected to the energy cell such that the first connector is electrically coupled to an anode of the energy cell and the second connector is electrically connected to a cathode of the energy cell. In another embodiment, the first connector is a male pin connector and the second connector is a female socket connector, and the first and second connectors are disposed at the outer peripheral edge of the photovoltaic collector such that the male pin connector is electrically connectable with a corresponding female socket connector of the first adjacent photovoltaic collector, and the female socket connector is electrically connectable with a corresponding male pin connector of the first adjacent photovoltaic collector. In another embodiment, the male pin connector is a flat or round pin connector, and the female socket connector is a flat or round receptacle connector.

In another embodiment, photovoltaic cell is a triangular photovoltaic cell, and the first and second connectors are disposed along a first edge of the triangular photovoltaic cell along an outer peripheral surface. In another embodiment, the first and second connectors disposed along the first edge of the triangular photovoltaic cell are positioned adjacent to each other proximal to a first vertex of the first edge of the triangular photovoltaic cell. In another embodiment, the first and second connectors disposed along the first edge of the triangular photovoltaic cell are positioned distal from each other such that the first connector is proximal to one vertex of the first edge of the triangular photovoltaic cell and the second connector is proximal to the other vertex of the first edge of the triangular photovoltaic cell. In another embodiment, the photovoltaic collector further includes: a second connection unit electrically connected to the power collar, and including first and second connectors respectively electrically connected to the positive and negative terminals of the power collar; and a third connection unit electrically connected to the power collar, and including first and second connectors respectively electrically connected to the positive and negative terminals of the power collar. The first and second connectors of the second connection unit are disposed along a second edge of the triangular photovoltaic cell along the outer peripheral surface, and the first and second connectors of the third connection unit are disposed along a third edge of the triangular photovoltaic cell along the outer peripheral surface.

In another embodiment, for each of the second and third connection units, the first and second connectors are disposed along a corresponding edge of the triangular photovoltaic cell so as to be positioned adjacent to each other proximal to a corresponding vertex of the triangular photovoltaic cell. In another embodiment, for each of the second and third connection units, the first and second connectors are disposed along a corresponding edge of the triangular photovoltaic cell so as to be positioned distal from each other and such that the first connector is proximal to one vertex of the corresponding edge of the triangular photovoltaic cell and the second connector is proximal to the other vertex of the corresponding edge of the triangular photovoltaic cell. In another embodiment, the first and second connectors of the second connection unit are configured to electrically connect and interlock the photovoltaic collector with a second adjacent photovoltaic collector, and wherein the first and second connectors of the third connection unit are configured to electrically connect and interlock the photovoltaic collector with a third adjacent photovoltaic collector.

In yet another embodiment, the photovoltaic cell is one of a rectangular photovoltaic cell, a pentangular photovoltaic cell, a hexangular photovoltaic cell, an elliptical photovoltaic cell, and a circular photovoltaic cell. In yet another embodiment, the photovoltaic collector further includes a second connection unit electrically connected to the power collar and including first and second connectors respectively electrically connected to the positive and negative terminals of the power collar. In yet another embodiment, the first connector is electrically connected to the positive terminal of the power collar via a first interconnect trace and the second connector is electrically connected to the negative terminal of the power collar via a second interconnect trace. In yet another embodiment, the first and second interconnect traces are embedded so as to be hermetically sealed within one or more protective layers of the photovoltaic collector, and wherein the first and second interconnect traces provide electrical conduits from the positive terminal and the negative terminal of the power collar to the first and second connectors, respectively, at the outer peripheral edge of the photovoltaic collector.

In yet another embodiment, a photovoltaic collector array comprises: a plurality of photovoltaic collectors, each photovoltaic collector including: a photovoltaic cell configured to absorb incident light and generate electric current; a power collar disposed along a periphery of the photovoltaic cell; and a plurality of connection units electrically connected to the power collar, wherein each connection unit is disposed at an outer peripheral edge of the photovoltaic collector, and is configured to electrically interconnect with an adjacent one of the plurality of photovoltaic collectors, and where the plurality of photovoltaic collectors tessellate by interconnecting with each other via the plurality of connection units of the plurality of photovoltaic collectors.

In yet another embodiment, each of the plurality of photovoltaic collectors is one of a triangular photovoltaic collector, a rectangular photovoltaic collector, a pentangular photovoltaic collector, a hexangular photovoltaic collector, an elliptical photovoltaic collector, and a circular photovoltaic collector. In yet another embodiment, the plurality of tessellating photovoltaic collectors are electrically connected to and interlocked with each other via only the plurality of connection units of the plurality of photovoltaic collectors, without requiring additional cable wires.

In yet another embodiment, a photovoltaic collector comprises: a photovoltaic cell including: a first conduction layer; a second conduction layer; and a photovoltaic layer configured to absorb incident light and generate electric current, wherein the photovoltaic layer is electrically connected to the first conduction layer on a first side of the photovoltaic layer and to the second conduction layer on a second side opposite the first side; where the first conduction layer is an ultrastatic conducting layer. In yet one or more embodiments, the ultrastatic conducting layer is made using ultrasonic spray technology, the ultrastatic conducting layer is transparent or translucent coating, the ultrastatic conducting layer includes silver nanowires and/or graphene, a thickness of the ultrastatic conducting layer is approximately 200 nanometers, and second conduction layer is another ultrastatic conducting layer made using ultrasonic spray technology.

In yet another embodiment, the photovoltaic layer is a plasmonic layer that includes polymer dispersed with nanoparticles, wherein the nanoparticles are tuned to a predetermined wavelength of incident light that induces electrons to oscillate at a surface of the nanoparticles, and the first and second conduction layers are configured to capture the oscillating electrons along the surface of the nanoparticles to generate an alternating current. The photovoltaic layer is a photonic absorption layer that is tuned to absorb incident light to generate a direct current along the first or second conduction layer. The second side of the photovoltaic layer is an incident surface side from where incident light enters the photovoltaic collector, and wherein the first side of the photovoltaic layer is a distal surface side that is opposite to the incident surface side.

In yet another embodiment, the photovoltaic cell is a plasmonic photovoltaic cell, and the photovoltaic layer is a plasmonic layer that includes polymer dispersed with nanoparticles, the nanoparticles are tuned to a predetermined wavelength of incident light that induces electrons to oscillate at a surface of the nanoparticles, and wherein the first and second conduction layers are configured to capture the oscillating electrons along the surface of the nanoparticles to generate an alternating current, and where the photovoltaic collector further comprises: a photonic photovoltaic cell including: a third conduction layer; and a photonic absorption layer that is electrically connected to the first conduction layer on the incident surface side and to the third conduction layer on the distal surface side, where the third conduction layer is another ultrastatic conducting layer. In yet another embodiment, the photonic absorption layer is tuned to absorb the incident light to generate a direct current along the first or third conduction layer, the second conduction layer is made of a conductive material or a semimetal material, wherein the second conduction layer is not made the ultrasonic spray technology, and the first and third conduction layers are made of conductive silver nanowires, the first and third conduction layers being made with the ultrasonic spray technology.

In yet another embodiment, a photovoltaic cell includes: a first conduction layer; a second conduction layer; and a photovoltaic layer configured to absorb incident light and generate electric current, wherein the photovoltaic layer is electrically connected to the second conduction layer on an incident surface side of the photovoltaic layer, the incident surface side being a side from where incident light enters the photovoltaic layer, and wherein the photovoltaic layer is further electrically connected to the first conduction layer on a distal surface side of the photovoltaic layer, the distal surface side being opposite to the incident surface side, where the first conduction layer is an ultrastatic conducting layer, said ultrastatic conducting layer being made by ultrasonic spray technology. In yet another embodiment, the ultrastatic conducting layer: (i) is transparent or translucent, (ii) includes at least one of silver nanowires and graphene, and (iii) has a thickness of approximately 200 nanometers, and the second conduction layer is a transparent conducting layer made of a conducting or semimetal material, the second conduction layer being not made by the ultrasonic spray technology.

In yet another embodiment, the photovoltaic cell further comprises a first diode layer sandwiched between the first conduction layer and the photovoltaic layer, and a second diode layer sandwiched between the photovoltaic layer and the second conduction layer, where the photovoltaic layer is a polymer layer with nanoparticles dispersed therein, wherein the polymer layer generates alternating current from the incident light, and where the photovoltaic layer is a semiconductor layer that implements quantum dots and that is configured to generate direct current from the incident light.

In yet another embodiment, the photovoltaic cell further comprises: a power collar connected to the first and second conduction layers to draw electric current based on the incident light being absorbed by the photovoltaic layer; and an energy cell being electrically coupled to the power collar, the energy cell configured to store the electric current generated by the photovoltaic cell, and a plurality of connection units, each connection unit including a male pin connector and a female socket connector, the plurality of connection units being disposed along on an outer peripheral edge of the photovoltaic cell, where each connection unit is in electric connection with the power collar and the energy cell, and where each connection unit is adapted to connect with an adjacent connection unit of an adjacent photovoltaic cell to tessellate and electrically interconnect and interlock the photovoltaic cell with a plurality of adjacent photovoltaic cells without requiring additional cable wires.

According to a first aspect, there is provided a photovoltaic cell, comprising: a first conduction layer; a second conduction layer; a photonic absorption layer electrically coupled to the first conduction layer, the photonic absorption layer is tuned to absorb incident light at a first wavelength of the incident light to generate a first electric current along the first conduction layer; and a plasma-sonic (also known as plasmonic) layer electrically coupled to the photonic absorption layer and the second conduction layer, the plasma-sonic layer includes nanoparticles, the nanoparticles are tuned to a second wavelength of the incident light that induces electrons to oscillate at a surface of the nanoparticles.

According to a second aspect, there is provided a solar photovoltaic collector, comprising: a photovoltaic cell of the first aspect; a first electrode electrically coupled to the first conduction layer, and a second electrode electrically coupled to the plasma-sonic layer and the photonic absorption layer, wherein the first electrode is electrically isolated from the second electrode.

According to a third aspect, there is provided a solar photovoltaic array, comprising: a plurality of solar photovoltaic collectors of the second aspect, configured to tessellate with each other.

In accordance with some examples, a photovoltaic cell comprises a first conduction layer; a second conduction layer; a photonic absorption layer electrically coupled to the first conduction layer (the photonic absorption layer configured to absorb incident light shorter than a first wavelength of the incident light to generate a first electric current along the first conduction layer); and a plasma-sonic layer electrically coupled to the photonic absorption layer and the second conduction layer, and the plasma-sonic layer includes nanoparticles configured to induce electrons to oscillate at a surface of the nanoparticles shorter than a second wavelength of the incident light.

In some examples, the photovoltaic cell further includes a rectifier bridge configured to provide a same polarity of output with respect to reference ground for any polarity at a first input or second input, wherein the first input is electrically coupled to the second conduction layer, and the second input is electrically coupled to the plasma-sonic layer. In some examples, the photovoltaic cell further includes an energy cell electrically coupled across the output of the rectifier bridge and the reference ground. In some examples, the photovoltaic cell further includes a substrate configured to hermetically seal the photonic absorption layer, the plasma-sonic layer, and the second conduction layer.

In accordance with some examples, a solar photovoltaic collector comprises at least one photovoltaic cell having a first conduction layer and a plasma-sonic layer, a first electrode electrically connected to the first conduction layer, and a second electrode electrically connected to the plasma-sonic layer and the photonic absorption layer. The first electrode is electrically isolated from the second electrode. The at least one photovoltaic cell further includes a second conduction layer, and a photonic absorption layer electrically coupled to the first conduction layer. The photonic absorption layer is configured to absorb incident light shorter than a first wavelength of the incident light to generate a first electric current along the first conduction layer, and where the plasma-sonic layer is electrically coupled to the photonic absorption layer and the second conduction layer, the plasma-sonic layer includes nanoparticles configured to induce electrons to oscillate at a surface of the nanoparticles shorter than a second wavelength of the incident light.

In some examples, the solar photovoltaic collector further includes a rectifier bridge configured to provide a same polarity of output with respect to reference ground for any polarity at a first input or second input, wherein the first input is electrically coupled to the second conduction layer, and the second input is electrically coupled to the plasma-sonic layer. In some examples, the solar photovoltaic collector further includes an energy cell electrically coupled across the output of the rectifier bridge and the reference ground. In some examples, the solar photovoltaic collector further includes a substrate configured to hermetically seal the photonic absorption layer, the plasma-sonic layer, and the second conduction layer.

In some examples, the solar photovoltaic collector further includes a power transfer circuit affixed to the photovoltaic collector and electrically coupled to the first electrode and the second electrode, wherein the power transfer circuit is configured to sense instantaneous power of an electrical power grid, sense instantaneous power generated from the photovoltaic collector, and sweep power generated from the photovoltaic collector to the electrical power grid.

In accordance with some examples, a solar photovoltaic collector array, comprises a plurality of solar photovoltaic collectors configured to tessellate with each other, and each photovoltaic collector includes: at least one photovoltaic cell having a first conduction layer and a plasma-sonic layer, a first electrode electrically connected to the first conduction layer, and a second electrode electrically connected to the plasma-sonic layer and the photonic absorption layer. The first electrode is electrically isolated from the second electrode. The at least one photovoltaic cell further includes a second conduction layer and a photonic absorption layer electrically coupled to the first conduction layer and the second conduction layer. The photonic absorption layer is configured to absorb incident light shorter than a first wavelength of the incident light to generate a first electric current along the first conduction layer, and where the plasma-sonic layer is electrically coupled to the photonic absorption layer and the second conduction layer, the plasma-sonic layer includes nanoparticles configured to induce electrons to oscillate at a surface of the nanoparticles shorter than a second wavelength of the incident light.

In some examples, the solar photovoltaic collector array further includes a rectifier bridge configured to provide the same polarity of output with respect to reference ground for any polarity at a first input or second input, wherein the first input is electrically coupled to the second conduction layer and the second input is electrically coupled to the plasma-sonic layer. In some examples, the solar photovoltaic collector array further includes an energy cell electrically coupled across the output of the rectifier bridge and the reference ground. In some examples, each photovoltaic collector further includes a substrate configured to hermetically seal the photonic absorption layer, the plasma-sonic layer, and the second conduction layer.

In some examples, each respective solar photovoltaic collector further includes a power transfer circuit affixed to the solar photovoltaic collector and electrically coupled to the first electrode and the second electrode, wherein the power transfer circuit is configured to sense instantaneous power of an electrical power grid, sense instantaneous power generated from the photovoltaic collector, and sweep power generated from the photovoltaic collector to the electrical power grid. In some examples, solar photovoltaic collector array further includes a mounting assembly configured to bracket the plurality of solar photovoltaic collectors of a building. Photovoltaic cells, photovoltaic collectors and photovoltaic arrays can be used in a number of applications, such as, for example, buildings, pavements, walls, homes, vehicles, planes, trains and ships.

### BRIEF DESCRIPTION OF THE DRAWINGS

For a better understanding of the various described examples, reference should be made to the description below and in conjunction with the following figures, in which like reference numerals refer to corresponding parts throughout the figures.

FIGS. 1A and 1B illustrate a front and side view of an exemplary plasmonic-based photovoltaic collector.

FIG. 2 illustrates front views of various shapes of exemplary plasmonic-based photovoltaic cells used for tessellating a photovoltaic collector array.

FIG. 3 illustrates various side views of exemplary plasmonic-based photovoltaic collectors.

FIGS. 4A-4C illustrate various cross-sectional views of exemplary plasmonic-based photovoltaic collectors.

FIGS. 5A and 5B illustrate various cross-sectional views of exemplary hybrid plasmonic-based photovoltaic collectors.

FIGS. 6A-6R illustrate cross-sectional views of various plasmonic-based and/or photonic-based photovoltaic collectors.

FIG. 7 illustrates an exploded view of exemplary plasmonic-based photovoltaic collector.

FIG. 8 illustrates an ISO view and bracketing coupler for an exemplary hybrid plasmonic-based photovoltaic collector.

FIGS. 9A and 9B illustrate an array of tessellated plasmonic-based collectors.

FIG. 10 illustrates a tessellated array that envelop one or more buildings.

FIG. 11 illustrates a conceptual data flow diagram illustrating the data flow between different hardware of a hybrid plasmonic-based photovoltaic collector that implements a plasmonic generator and a photonic generator.

FIGS. 12A-12D illustrate front views of exemplary photovoltaic collectors with one or more connection units for interconnection in accordance with one or more embodiments.

FIG. 13 illustrates perspective views of multiple photovoltaic collectors interconnected to form a tessellated photovoltaic array in accordance with one or more embodiments.

While certain embodiments will be described in connection with the illustrative embodiments shown herein, the subject matter of the present disclosure is not limited to those embodiments. On the contrary, all alternatives, modifications, and equivalents are included within the spirit and scope of the disclosed subject matter as defined by the claims. In the drawings, which are not to scale, the same reference numerals are used throughout the description and in the drawing figures for components and elements having the same structure.

### DETAILED DESCRIPTION

The detailed description set forth below in connection with the appended drawings is intended as a description of various configurations and is not intended to represent the only configurations in which the concepts described herein can be practiced. The detailed description includes specific details for the purpose of providing a thorough understanding of various concepts. However, it will be apparent to those skilled in the art that these concepts can be practiced without these specific details. In some instances, well-known structures and components are shown in block diagram form in order to avoid obscuring such concepts.

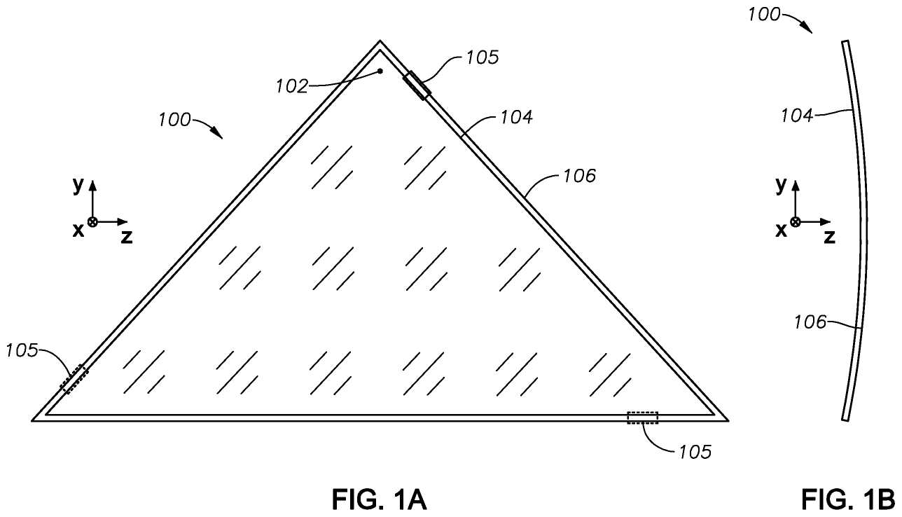

Examples of photovoltaic collectors will now be presented with reference to various electronic devices. These electronic devices will be described in the following detailed description and illustrated in the accompanying drawing by various blocks, components, circuits, steps, etc. (collectively referred to as “elements”). By way of example, an element, or any portion of an element, or any combination of elements of the microcontroller/processor 102 (FIG. 1A) can be implemented using one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionalities described throughout this disclosure. One or more processors in the processing system can execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more examples, the aspects of photovoltaic collectors can be implemented in hardware, software, or any combination thereof. The aspects implemented in software can be stored or encoded as one or more instructions or code on a computer-readable medium. Computer-readable media can include transitory or non-transitory computer storage media for carrying or having computer-executable instructions or data structures stored thereon. Both transitory and non-transitory storage media can be any available media that can be accessed by a computer as part of the processing system. By way of example, and not limitation, such computer-readable media can include a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer-executable code in the form of instructions or data structures accessible by a computer. Further, when information is transferred or provided over a network or another communications connection (either hardwired, wireless, or combination thereof) to a computer, the computer or processing system properly determines the connection as a transitory or non-transitory computer-readable medium, depending on the particular medium. Thus, any such connection is properly termed a computer-readable medium. Combinations of the above should also be included within the scope of the computer-readable media. Non-transitory computer-readable media exclude signals per se and the air interface.

The present disclosure describes a hybrid photovoltaic collector that includes a photonic absorption layer and a plasma-sonic layer, alternatively referred to as a plasmonic layer. The photonic absorption layer is configured to generate electron-hole pairs from incident light. In some configurations, the photonic absorption layer is configured to generate electron-hole pairs from incident light with wavelengths shorter than 700 nanometers, which corresponds to frequencies in the visible and ultraviolet spectrum. In some configurations, the photonic absorption layer is configured to generate electron-hole pairs from incident light with wavelengths greater than 700 nanometers, which corresponds to frequencies in the infrared spectrum. The generation of the electron-hole pairs of the photonic absorption layer induces a direct electric current in a conduction layer that is electrically coupled to a power collar at a periphery of the hybrid photovoltaic collector. In addition to the photonic absorption layer, the plasmonic layer functions in parallel to provide electrical current to the power collar. In particular, the plasmonic layer, with plasmonic-type properties, is configured to induce charged carrier (e.g., electrons, holes, etc.) oscillations from incident light. In some configurations, the plasmonic layer is configured to induce charged carrier (e.g., electrons, holes, etc.) oscillations from incident light shorter than 700 nanometers, which corresponds to frequencies in the visible and ultraviolet spectrum. In some configurations, the plasmonic layer is configured to induce charged carrier (e.g., electrons, holes, etc.) oscillations from incident light longer than 700 nanometers, which corresponds to frequencies in the infrared spectrum. The charged carriers (e.g., electrons, holes, etc.) generate an alternating current that, when coupled to the power collar at the periphery of the hybrid photovoltaic collector, rectifies and directs the current to an energy cell or inverter for future use.

FIGS. 1A and 1B illustrate a front and side view of an exemplary plasmonic-based photovoltaic collector 100. In this example, the photovoltaic collector 100 has a triangular shape and includes a microcontroller/processor 102, a power collar 104, connection unit 105, and an energy cell 106. The photovoltaic collector 100 can be an equilateral triangular shape, where each of the three edges has the same length, an isosceles triangular shape, where two of the three edges have the same length, or a scalene triangular shape, where none of the three edges have the same length.

As depicted in FIG. 1A, the microcontroller/processor 102 is situated near an apex of a triangle corner. In this instance, the microcontroller/processor 102 is embedded within the photovoltaic collector 100. That is, the microcontroller/processor 102 is fabricated within one or more protective layers of the photovoltaic collector 100 so as to be hermetically sealed within the photovoltaic collector 100, which protects the microcontroller/processor 102 from the elements (e.g., rain, snow, wind, dust, etc.) and ensures that peripheries to the microcontroller/processor 102 are correctly connected at fabrication. In some configurations, the microcontroller/processor 102 is provided on an insulating surface and electrically coupled to the portions of the photovoltaic collector 100.

As such, the microcontroller/processor 102 is standalone from the photovoltaic collector 100, and either can be modified individually. In some configurations, the microcontroller/processor 102 includes redundancy. For example, in some instances, a first microcontroller/processor 102 can be embedded and a second microcontroller/processor 102 can be provided on an insulating surface and electrically coupled to the portions of the photovoltaic collector 100. In other configurations, microcontroller/processors 102 are situated at two or more apexes of a triangle corner.

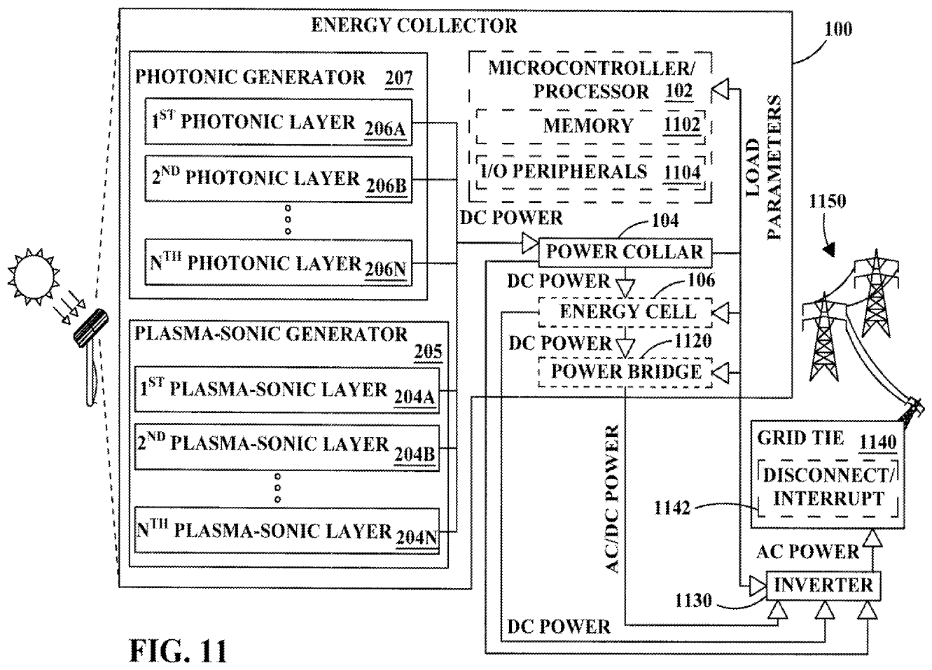

Further, the microcontroller/processor 102 includes memory electrically coupled to one or more processors. In general, the microcontroller/processor 102 includes one or more programmable input/output peripherals 1104 (see FIG. 11). For example, at least one programmable input/output peripheral can be a voltage sensor situated at an anode and/or cathode of the energy cell 106. In such a configuration, the voltage sensor is configured to detect the instantaneous voltage at an anode and/or a cathode of the photovoltaic collector 100 or of the energy cell 106. In some examples, at least one programmable input/output peripheral is a current sensor configured to detect current from the anode and/or the cathode of the photovoltaic collector 100 or of the energy cell 106. In some examples, at least one programmable input/output peripheral is an impedance sensor configured to detect the impedance of an electrical power grid. In some examples, at least one programmable input/output peripheral is a communication interface circuit to communicate with a power bridge or power inverter. In some instances, the communication interface circuit includes a universal serial bus (USB) configured to interface with an energy cell, power bridge, power inverter, grid-tie, or other electronic device to balance the load and facilitate power distribution.

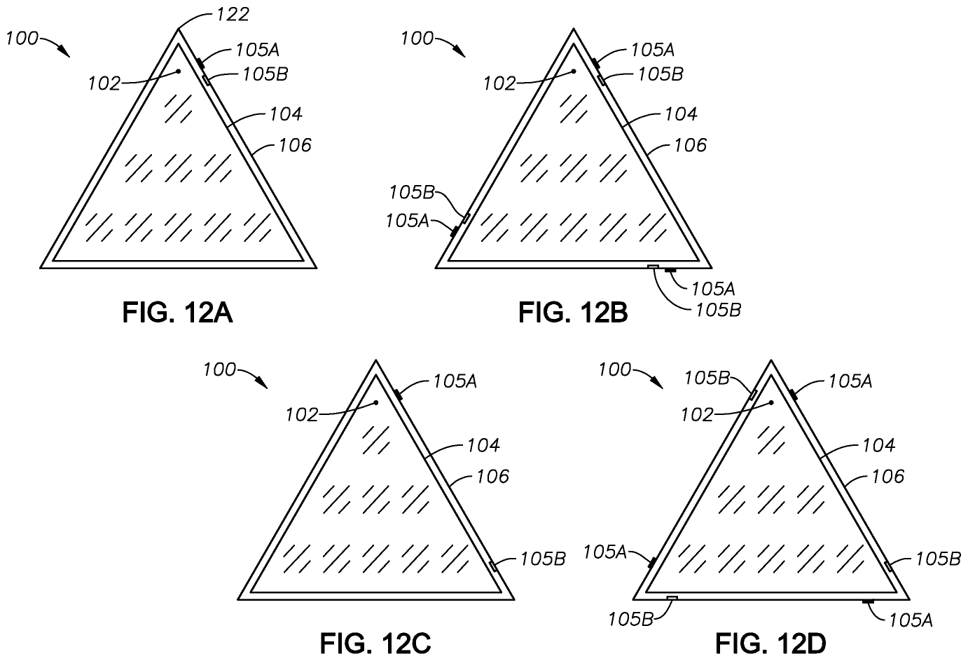

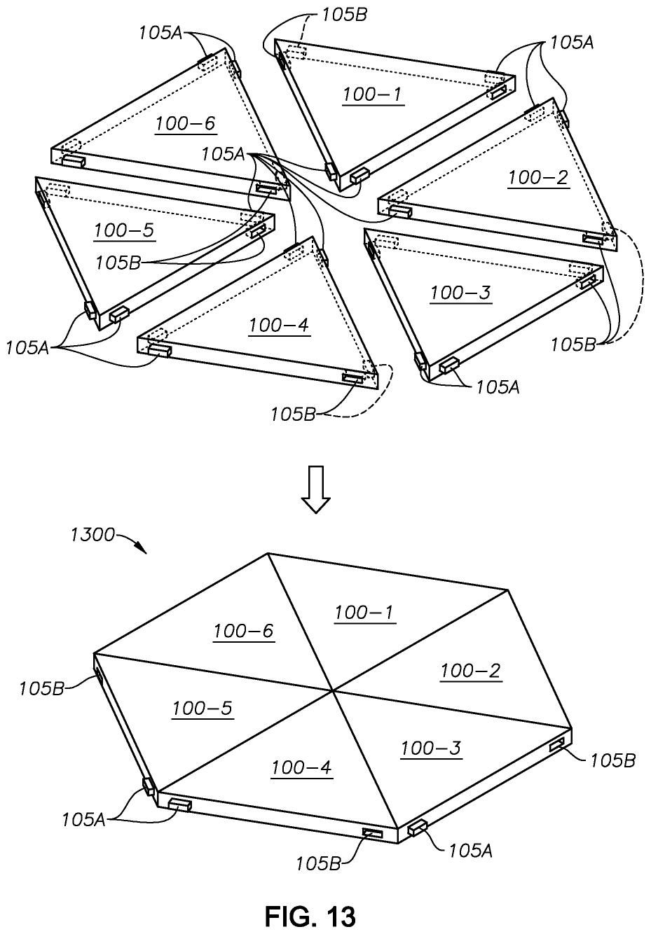

As depicted in FIG. 1A, the power collar 104 is situated around a periphery of the edges of the triangular photovoltaic collector 100. The power collar 104 is configured to direct charged carriers (e.g., electrons, holes, etc.) to energy cell 106 or inverter 1130 (FIG. 11). The power collar 104 is electrically coupled to at least one conduction layer and is made from semiconductor materials, such as silicon (polycrystalline silicon or monocrystalline silicon), germanium, cadmium telluride, copper indium gallium selenide, gallium arsenide (GaAs), indium gallium arsenide, and the like. The power collar 104 is further configured to electrically couple with one or more adjacent photovoltaic collectors. As shown in further detail below in connection with FIGS. 12-13, the power collar 104 may include a socketing feature, such as a male and a female connector to connect (e.g., electrically couple) with adjacent photovoltaic collectors. That is, a first photovoltaic collector 100 may interlock with a second photovoltaic collector 100 along a respective edge of the photovoltaic collector 100 so as to electrically couple the power collars 104 of each respective photovoltaic collector 100. In some instances, one or more adjacent photovoltaic collectors tessellate (e.g., situated with little to no gap between adjacent photovoltaic collectors) with the photovoltaic collector 100.

As depicted in FIG. 1A, the energy cell 106 is situated at edges of the photovoltaic collector 100. The energy cell 106 includes an anode (e.g., positive terminal) and a cathode (e.g., negative terminal). The energy cell 106 can be a battery, a capacitor, or other electrical energy storing device capable of storing a charge. The energy cell 106 provides a reservoir of electrical storage and provides a low-impedance path to the alternating current (e.g., IAC) thereby cancelling cyclical charges (e.g., ripple). In some examples, the energy cell 106 is a lithium-ion (Li-ion) cell. In some instances, the energy cell 106 is a battery with one or more energy cells. In some instances, the energy cell 106 is a Li-ion battery. In some instances, the energy cell 106 is a lithium polymer battery. In some examples, the energy cell 106 is based on at least one of lithium cobalt oxide (LiCoO₂), lithium iron phosphate (LiFePO₄), lithium ion manganese oxide (LiMn₂O₄, Li₂MnO₃, or LMO), lithium nickel manganese cobalt oxide (LiNiMnCoO₂ or NMC), lithium nickel cobalt aluminum oxide (LiNiCoAlO₂ or NCA), lithium titanate (Li₄Ti₅O₁₂ or LTO), and lithium-sulfur (LS). In some examples, the energy cell 106 is a nickel-metal hydride (NiMH) battery.

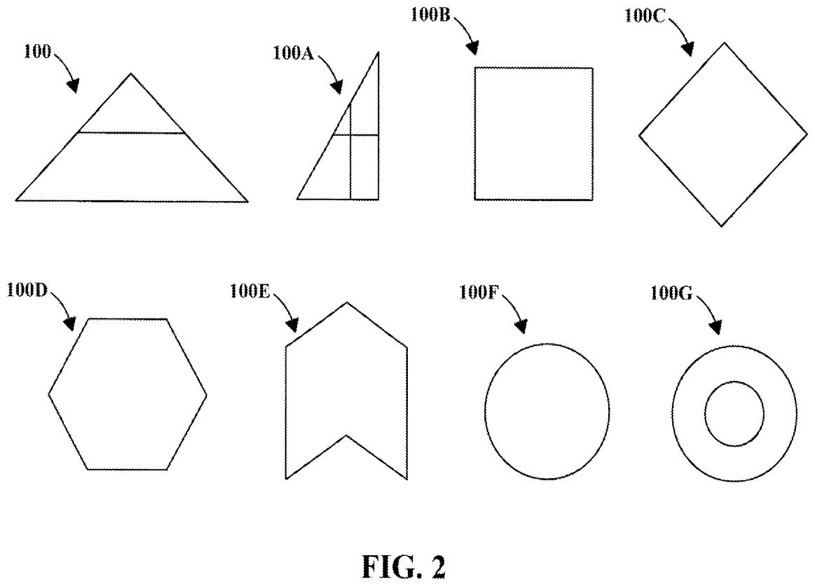

The position of the energy cell 106 and the power collar 104 are at the periphery and edges of the photovoltaic collector 100 so as to tessellate with adjacent photovoltaic collectors without overlaps or gaps. FIG. 2 illustrates front views of various shapes of exemplary plasmonic-based photovoltaic cells (e.g., photovoltaic collectors 100A-100G) used for tessellating a photovoltaic collector array. For example, the photovoltaic collector 100 when viewed from the front can be a polygon. For instance, the photovoltaic collector can be an equilateral/isosceles triangular photovoltaic collector 100 or a scalene triangular photovoltaic collector 100A. In some instances, the photovoltaic collector 100 is a square/rectangular photovoltaic collector 100B. In some instances, the photovoltaic collector 100 is a rhombic/diamond-shaped photovoltaic collector 100C. In some instances, the photovoltaic collector 100 is a hexagonal photovoltaic collector 100D. In some instances, the photovoltaic collector 100 is an arrow-shaped photovoltaic collector 100E. In other examples, the photovoltaic collector 100 when viewed from the font is curved. For instance, the photovoltaic collector 100 can have a circular photovoltaic collector 100F or a ring-shaped photovoltaic collector 100G. It should be appreciated that one or more different shaped photovoltaic collectors 100 can be tessellated together. For example, the circular photovoltaic collector 100F can be interlocked (e.g., tessellated, electrically coupled) into the opening of ring-shaped 100G. Likewise, hexagonal photovoltaic collector 100D can be interlocked (e.g., tessellated, electrically coupled) with any of the triangular photovoltaic collectors 100, the scalene triangular photovoltaic collector 100A, the square/rectangular photovoltaic collector 100B, the rhombic/diamond-shaped photovoltaic collector 100C, and the arrow-shaped photovoltaic collector 100E.

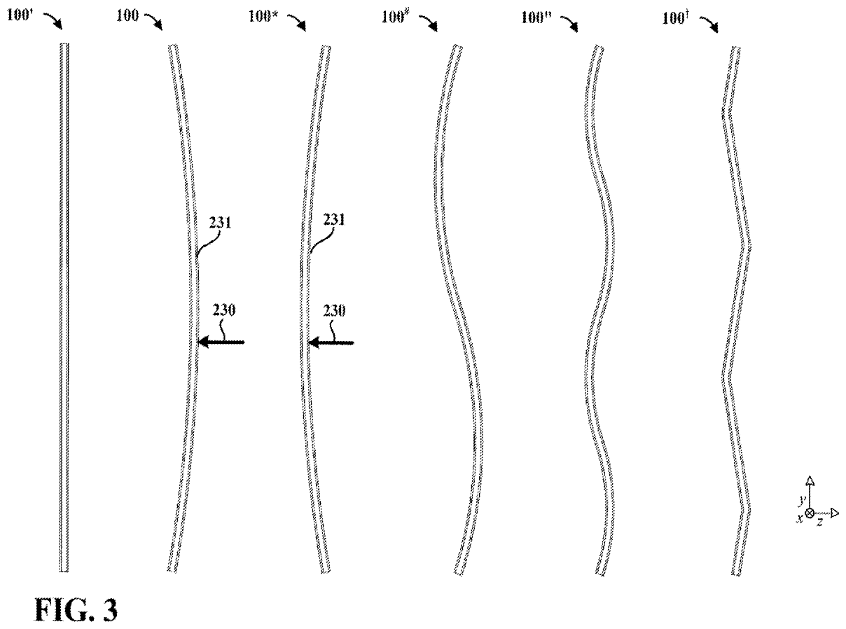

As depicted in FIG. 1B, the photovoltaic collector 100 can also be non-planar (e.g., curved). A curved photovoltaic collector (e.g., with an angle of 23.5°) can lens incident light thereby increasing absorption efficiency on a photonic absorption layer or increasing efficiency from charged carrier (e.g., electrons, holes, etc.) oscillations extraction in a plasmonic layer (plasma-sonic layer). Other curved and/or jagged shapes are contemplated. For example, FIG. 3 illustrates various side views of exemplary plasmonic-based photovoltaic collectors (e.g., cells, panels). In particular, a photovoltaic collector can be flat or planar as depicted in flat photovoltaic collector 100′ (FIG. 3). In some examples, the photovoltaic collector when viewed from the side can be elongated toward an incident surface 231 surface of incident light as depicted in the triangular photovoltaic collector 100 (e.g., convex) or can be elongated away from an incident surface 231, as depicted in the concave photovoltaic collector 100* (FIG. 3).

In some examples, the photovoltaic collector when viewed from the side can include a single undulation as depicted in single-undulated photovoltaic collector 100# (FIG. 3). In some examples, the photovoltaic collector when viewed from the side can include multiple undulations as depicted in the multiple-undulated photovoltaic collector 100″ (FIG. 3). In some examples, the photovoltaic collector when viewed from the side can be jagged, as depicted in jagged photovoltaic collector 100†. In some configurations, the solar photovoltaic collector 100 is non-planar along a light incident surface. In some configurations, the solar photovoltaic collector 100 is curved along a light incident surface at an arc angle between 0 to 23.5 degrees.

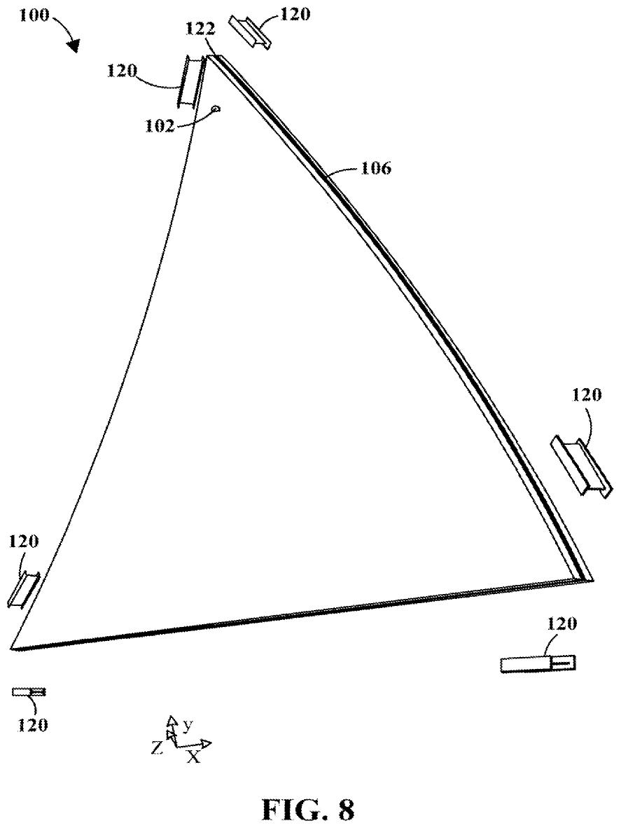

The curvature or surface of various side views of the photovoltaic collectors 100 can change with direction. For example, a surface can elongate towards incident light as depicted in the triangular photovoltaic collector 100 (e.g., convex) of FIG. 3 and can extend in the x-y plane and the y-z plane to form paraboloid-like or spherical-like surface, etc. (FIG. 8). It should also be appreciated that various combinations of the above shapes are contemplated. For example, a photovoltaic collector can have multiple undulations (e.g., 100″(FIG. 3)) and be hexagonally shaped (e.g., 100D (FIG. 2)).

Each photovoltaic collector 100 shown in one or more of FIGS. 1-3 can include structure and corresponding circuitry for interconnecting (e.g., tessellating, electrically coupling, electrically connecting, interlocking, and the like) multiple photovoltaic collectors 100 that are adjacent to each other.

One mechanism to interconnect multiple photovoltaic collectors (e.g., modules) may be to implement, for each photovoltaic collector 100, cable wires coupled to the anode and cathode of the power collar 104 and/or the energy cell 106 via a bridge circuit, and couple a junction box to the cable wires. However, this interconnection mechanism with the cable wires and the junction box can lead to increased costs and make each photovoltaic module bulkier. Further, this interconnection mechanism can lead to an unimpressive cosmetic appearance, and increased labor costs for the installation and interconnection.

To overcome the above problems, photovoltaic collectors 100 are equipped with one or more connection units 105, as shown in FIGS. 1A, 12A-12D, and 13. FIGS. 12A-12D illustrate front views of exemplary photovoltaic collectors 100 equipped with one or more connection units 105. Although not specifically shown in FIGS. 1A and 12A-12D, interconnect traces (e.g., electronic couple traces) made from a conductive material (e.g., copper, aluminum, polysilicon, stainless steel, graphene, and the like) may be embedded so as to be fabricated within one or more protective layers of photovoltaic collector 100 and be hermetically sealed within photovoltaic collector 100. The interconnect traces may be configured to provide electrical conduits from a positive terminal (anode) of power collar 104 or energy cell 106 and a negative terminal (cathode) of power collar 104 or energy cell 106 embedded within layers of photovoltaic collector 100, to one or more connection units 105, such that the positive terminal (anode) of power collar 104 or energy cell 106 is connected to male pin connector 105A and the negative terminal (cathode) of power collar 104 or energy cell 106 is connected to female socket connector 105B, at the edge of photovoltaic collector 100.

Thus, as shown in FIG. 12A, male pin connector 105A and female socket connector 105B are electrically coupled to power collar 104 (or energy cell 106) of photovoltaic collector 100, and connection unit 105 (including connectors 105A and 105B) provide a connection mechanism to interconnect (e.g., electrically couple) photovoltaic collector 100 and an adjacent photovoltaic collector.

Male pin connector 105A may be a mini pin male connector and female socket connector 105B may be a mini mating socket (or receptacle) female connector that are disposed at the edge of collector 100, as shown in FIGS. 12A-D and 13. For example, the mini pin male connector and mini mating female connector may be mini-USB connectors that are widely used in IoT and smart electronic devices. Design, shape, and type of male pin connector 105A and female socket connector 105B is not intended to be limiting. For example, connectors 105A and 105B may be flat or round pin and receptacle connectors.

As shown in FIGS. 12A-12B, the location and number of connection units 105 disposed on each photovoltaic collector 100 is not intended to be limiting. For example, FIG. 12A illustrates photovoltaic collector 100 with connection unit 105 (including connectors 105A and 105B) disposed along one of the three edges thereof. As shown in FIG. 12A, connection unit 105 is positioned along the edge and proximal to an apex of triangle corner 122. As another example, FIG. 12B illustrates photovoltaic collector 100 with connection units 105 (each including connectors 105A and 105B) respectively disposed along each of the three edges thereof. As shown in FIG. 12B, connection units 105 are respectively positioned along the three edges and proximal to three triangle corners of the triangular photovoltaic collector 100.

Further, as shown in FIGS. 12A-12D, the distance between connectors 105A and 150B of each connection unit 105 is not intended to be limiting. For example, as shown in FIGS. 12A-12B, connectors 105A and 150B of each connection unit 105 may be disposed along the edge so as to be in close proximity to each other. Alternately, as shown in FIGS. 12C-12D, connectors 105A and 150B of each connection unit 105 may be disposed along the edges so as to be spaced apart from each other.

FIG. 13 illustrates perspective views of six photovoltaic collectors 100-1 to 100-6 interconnected to form tessellated photovoltaic array 1300. As shown in FIG. 13, each of the photovoltaic collectors 100-1 to 100-6 has connectors 105A and 150B disposed along each edge thereof. The male pin connectors 105A are adapted to mate with female socket connectors 105B of adjacent photovoltaic collector 100 such that the photovoltaic collectors 100-1 to 100-6 interconnect via the connectors 105A and 150B to electrically couple photovoltaic collectors 100-1 to 100-6 to each other and to hold photovoltaic collectors 100-1 to 100-6 in place relative to each other. Although tessellated photovoltaic array 1300 in FIG. 13 is hexagonal, other desired shapes can be designed with various shapes of photovoltaic collectors 100 such as square/rectangular photovoltaic collectors, rhombic/diamond-shaped photovoltaic collectors, and the like.

By implementing power trace and bringing power collar 104 or energy cell 106 positive and negative terminals to the edge of the module, and equipping the edge with mini male plug and female receptacle connectors, a simple and efficient interconnect mechanism to electrically couple adjacent modules can be implemented. Modules with the interconnect mechanism shown in FIGS. 12A-D and 13 can be interconnected without hardwired cables and to achieve any desired shape for the tessellated module array without any visible wires or cables.

The photovoltaic collectors 100 equipped with one or more connection units 105 as shown in FIGS. 1A, 12A-D, and 13 produce several advantages. First, since the male plug and female socket connectors 105A and 105B are built into each photovoltaic collector 100 during manufacturing, no external wiring or connector parts are needed during installation and creation of the tessalated module array. Second, connectors 105A-B can be made in different sizes depending on the size of the module 100 for power voltage and current carry. Third, connectors 105A-B can be disposed on each edge of the module 100 for each interconnect to form any shape desired. Fourth, equipping photovoltaic collectors 100 with connection units 105 leads to reduced labor and material costs.

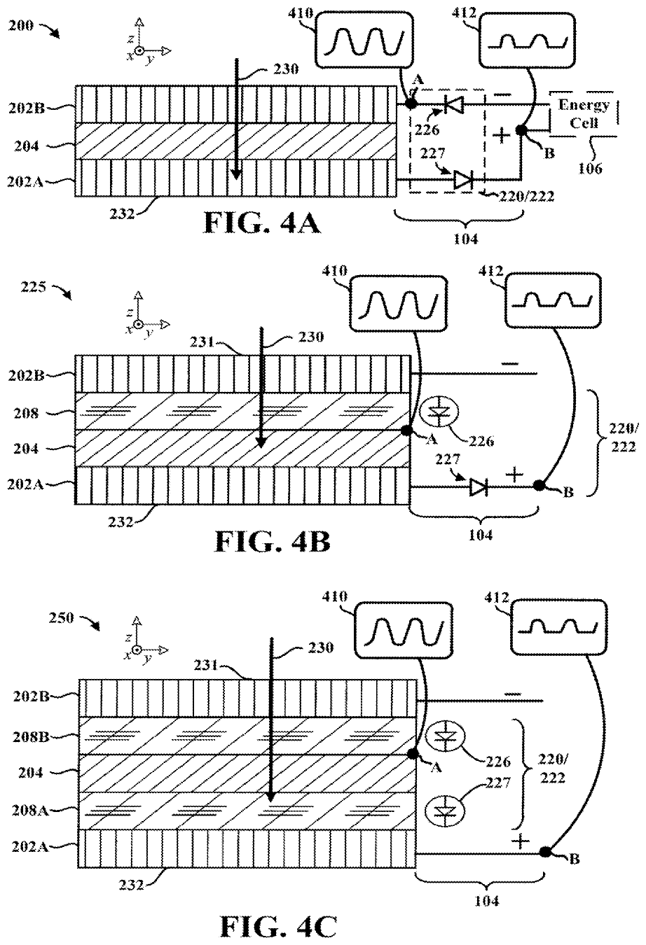

FIGS. 4A-4C illustrate various cross-sectional views of exemplary plasmonic-based (plasma-sonic-based) photovoltaic cells. The plasmonic photovoltaic cell cross section 200 depicted in FIG. 4A includes a first conduction layer 202A, a plasmonic (plasma-sonic) layer 204 (e.g., photovoltaic layer), and a second conduction layer 202B. The first conduction layer 202A and the second conduction layer 202B can be made of a conductive material, such as metal, alloy, or a semiconductor (e.g., copper, aluminum, polysilicon, stainless steel, and the like). The first conduction layer 202A and the second conduction layer 202B can also be made from a semimetal, such as graphene, arsenic, antimony, etc. In some examples, the first conduction layer 202A and/or the second conduction layer 202B is made from a p-doped or n-doped semimetal (e.g., graphene, arsenic, antimony, etc.).

In some embodiments, one or both of the first conduction layer 202A and the second conduction layer 202B can be an ultrastatic conducting layer. As used herein, the term “ultrastatic conducting layer” refers to a conduction layer that is ultrasonically coated onto a substrate using an ultrasonic spray nozzle. The ultrastatic conducting layer can include conductive material or semimetal material like conductive nanowires (e.g., metallic nanowires, semimetal nanowires, doped semimetal nanowires), nanotubes (e.g., carbon nanotubes), or graphene. For example, first conduction layer 202A can be a first ultrastatic conducting layer applied using ultrasonic spray technology to the distal surface side of plasmonic layer 204, and second conduction layer 202B can be layer made of conductive or semimetal material that is applied using coating techniques other than ultrasonic spray technology. As another example, both first and second conduction layers 202A and 202B can be ultrastatic conducting layers coated onto the plasmonic layer 204. As depicted in FIG. 4A, a surface of both the first conduction layer 202A and the second conduction layer 202B is electrically coupled to the plasmonic layer 204 along an interface in a transverse direction (e.g., x-y plane).

Compared to conventional spray coating systems (e.g., air pressure based coating systems), ultrasonic spray technology offers the advantage of more precise, more controllable, more repeatable, and more environmentally friendly conducting layer coatings. Ultrasonic spray technology utilizes ultrasonic spray nozzles that emit unpressurized, low-velocity spray that can be easily controlled and that significantly reduces the amount of overspray since the drops settle on the substrate, rather than bouncing off it. This translates into substantial material savings and reduction in emissions into the environment. The ultrasonic spray nozzles are inherently non-clogging, self-cleaning devices due to continuous ultrasonic vibrations and their relatively large orifice. Ultrasonic spray nozzles can be fabricated from titanium for long life and excellent acoustical properties. Ultrasonic spray technology enables extremely low flow rates when applying and creating the ultrastatic conducting layer. In addition, applying the ultrastatic conducting layer using the ultrasonic spray technology offers the benefit of spraying conducting layer particles in suspension, and keeping the particles evenly suspended during the entire spray process through the ultrasonic action of the ultrasonic spray nozzle. This results in more uniform dispersion of particles in thinner layers.

During the coating process of the ultrastatic conducting layer (e.g., using Sono-Tek Corporation ultrasonic nozzle technology), ultrasonic spray nozzles and atomizing devices are used to coat projected or suspended fluid (e.g., ultrastatic fluid) on the target surface (e.g., on plasmonic layer 204 of FIG. 4A) with very high accuracy. The ultrasonic nozzle is an ultrasonic atomizing device based on the principle of a horn transducer. The ultrasonic nozzle is used for applying nano- or sub-micron functional coatings, and for other applications like ultrasonic spray pyrolysis, ultrasonic spray drying and the like. The ultrasonic nozzle has the advantages of uniform atomization particles, high precision, extremely low air pressure, high transfer efficiency of raw materials, non-clogging, and the like. Unlike conventional pressure nozzles, ultrasonic spray nozzles do not force liquids through a small orifice using high pressure in order to produce a spray. Rather, liquid (e.g., ultrastatic fluid) is fed through the center of a nozzle with a relatively large orifice, without pressure, and is atomized due to ultrasonic vibrations in the nozzle. A precision ultrasonic generator provides the mechanical energy required to create the vibrations in the nozzle.

The conductive or semimetal material of the ultrastatic fluid used to create the ultrastatic conducting layer may be a conductive material that includes nanowires (e.g., metallic nanowires, silver nanowire, semimetal nanowires, doped semimetal nanowires), nanotubes (e.g., carbon nanotubes), and/or graphene. For example, the ultrastatic fluid sprayed from the ultrasonic spray nozzle may include one or more of 4H structural silver nanowires (4H-AgNW), face-centered cubic (FCC) silver nanowires (FCC-AgNW), graphene, and the like. A median diameter of the silver nanowires may be around 30 nm. As another example, the ultrastatic fluid may include only graphene.

Graphene is a form of carbon that occurs in one-atom-thick sheets and has useful electrical properties. It readily conducts electricity and has excess electrons that can move easily. It is flexible, robust, and transparent, and it is made from inexpensive and ubiquitous carbon. Graphene has high electron mobility that is 100× faster than silicon, it conducts heat 2x × better than diamond, its electrical conductivity is 13× better than copper, it absorbs only 2.3% of reflecting light, it is impervious so that even the smallest atom (helium) can't pass through a defect-free monolayer graphene sheet. To enable the photovoltaic cell to generate electricity more efficiently, the ultrastatic conducting layer (e.g., first conduction layer 202A) could be a thin layer of graphene. In this case, the ultrastatic fluid that is sprayed ultrasonically from the ultrasonic spray nozzle could include graphene as the active element, and the coated ultrastatic conducting layer could be a layer of graphene. An ultrastatic conducting layer made of graphene can be just 1 nanometer thick—a fraction as thick as a conventional indium tin oxide (ITO) conduction layer. The high electronic conductivity, flexibility, and transparency of graphene makes it useful in heterojunction solar cells, where they can be applied in a number of different ways including electrodes (both cathodes and anodes), donor layers, buffer layers, acceptor layers and active layers.

Since the ultrasonic nozzle utilized to coat the ultrastatic conducting layer operates at a specific resonant frequency, the frequency of the ultrasonic nozzle dictates the median droplet size of the ultrastatic fluid sprayed from the nozzle. The droplet sizes have little variance, and can be mathematically calculated to fall within a tight predicted drop distribution. For example, a 120 kHz nozzle produces a median drop size of 18 microns (when spraying water). The higher the frequency, the smaller the median drop size. The nozzle is fabricated from a very high-strength titanium alloy and other proprietary metals, making them exceptionally resistant to chemical attack and providing superior acoustical properties. The electrically active elements are contained within a sealed housing that protects the nozzle components from external contamination. A liquid feed tube runs the entire length of the nozzle. The nozzle's design ensures that the ultrastatic fluid only comes into contact with titanium within the nozzle.

Utilizing the above described ultrasonic spray technology for creating the ultrastatic conducting layer leads to 80% reduction in spray material required and 50% reduction in spray waste and energy usage during the ultrasonic nanocoating process over current industry standards utilizing conventional techniques for coating or applying the conduction layers for photovoltaic collectors, while maintaining high levels of accuracy (e.g., in range of around 100-400 nanometers).

With the above described ultrasonic nozzle technology, the ultrastatic conducting layer is applied to the distal surface side of plasmonic layer 204 of FIG. 4A as the first conduction layer 202A. Optionally, a second ultrastatic conducting layer is applied to front surface side of plasmonic layer 204 of FIG. 4A as the second conduction layer 202B. The ultrastatic conducting layer may be transparent. A thickness of the ultrastatic conducting layer may be in the range of 80-300 nm (nanometers), and more preferably, approximately 200 nm.

Creating the ultrastatic conducting layer using the ultrasonic spray technology provides a greater degree of accuracy since surface materials are applied at a molecular level. Other advantages of utilizing ultrasonic spray technology to create conduction layers 202A and/or 202B as ultrastatic conducting layers include: reduced material consumption and overspray by up to 80% while increasing throughput and providing uniform layer application, highly controllable spray patterns for reliable, consistent results, corrosion-resistant ultrasonic spray nozzle construction, ultra-low flow rate capabilities, low maintenance and non-clogging design of the ultrasonic spray nozzle, reduced downtime in the manufacturing process, and high reliability with no moving parts. Still further, the ultrasonic spray technology leads to additional advantages including: ability to precisely control atomized drop size (and resulting thickness of the ultrastatic conducting layer) by selectively setting nozzle frequency, and achieving a tight drop distribution allowing for optimized coating morphology. Yet still further, utilizing the ultrasonic spray technology for coating the ultrastatic conducting layer leads to additional advantages including: spraying of nanoparticle solutions with significantly less agglomeration than conventional methods, optimized coating from 5μ (microns) down to 0.1μ over conventional coating techniques, increased uniformity from ±10% down to ±2% over conventional coating techniques, and optimized coating morphologies from a grainy (porous) structure to continuous (glossy) smooth layer.

The plasmonic layer 204 can be made from a dielectric (e.g., electrical insulator) or semiconductor. The plasmonic layer 204 can be a polymer or a ceramic. In some examples, the plasmonic layer 204 is a polycarbonate. In general, the plasmonic layer 204 is non-conductive to direct current (e.g., IDc) but is conductive to alternating current (e.g., IAc). As such, plasmonic layer 204 is configured to be polarized in the presence of an electric field. This polarization causes positive charges to be displaced toward the electric field and negative charges to be displaced away from the electric field, which creates an internal electric field thereby reducing the overall electric field within the dielectric itself. The plasmonic layer 204 includes nanoparticles that couple with the polarization of the dielectric and induce electrons to oscillate at a surface of the nanoparticles within the dielectric for certain wavelengths of incident light. It should be appreciated that the induced electron oscillations occur throughout the dielectric and are not simply concentrated at an interface between the dielectric and an adjacent conduction layer (e.g., the first conduction layer 202A (e.g., first ultrastatic conducting layer) and the second conduction layer 202B (e.g., second ultrastatic conducting layer)). In some instances, the wavelength of incident light is at a resonance wavelength of the charged carriers (e.g., electrons, holes, etc.).

The wavelengths of incident light that induce electrons to oscillate at a surface of the nanoparticles correlate with the size of the nanoparticles. As such, the wavelengths of incident light can be tuned by increasing or decreasing the size of the nanoparticles. In some examples, the wavelength of incident light is tuned to be longer than 700 nanometers, which corresponds to frequencies in the infrared spectrum. In some examples, the wavelength of incident light is tuned shorter than 700 nanometers, which corresponds to frequencies in the visible light and ultra-violet spectrum.

In some examples, the plasmonic layer 204 is an electrical insulator. In some examples, the plasmonic layer 204 is a dielectric with a complex dielectric constant. In some examples, the nanoparticles contribute to the plasmonic layer 204 having a complex dielectric constant. The nanoparticles can be homogenously dispersed (e.g., mixed) throughout the plasmonic layer 204 and can be a dielectric, a semiconductor, a semimetal, or a metal. The shape of the nanoparticles can be substantially similar or vary. The shape can have any one of a conical, rectangular, bi-pyramidal, tetrahedral, cubical, octahedral, cylindrical, ellipsoidal, or spherical shape. In some examples, the nanoparticles are dielectrics that are suspended in a polymer matrix. In some examples, the nanoparticles are dielectrics that are suspended in a polycarbonate. In some examples, the nanoparticles are dielectrics that are suspended in a ceramic matrix.

A surface of the first conduction layer 202A (e.g., first ultrastatic conducting layer) is electrically coupled to the plasmonic layer 204 along an interface in a transverse direction (e.g., x-y plane). This configuration facilitates capturing the oscillation of charged carriers (e.g., electrons, holes, etc.) of the nanoparticles in the plasmonic layer 204 at the first conduction layer 202A to generate an alternating electric current along the first conduction layer 202A. Likewise, a surface of the second conduction layer 202B (e.g., second ultrastatic conducting layer) is electrically coupled to the plasmonic layer 204 along an interface in a transverse direction (e.g., x-y plane). This configuration facilitates capturing the oscillation of charged carriers (e.g., electrons, holes, etc.) of the nanoparticles in the plasmonic layer 204 at the second conduction layer 202B to generate an alternating electric current along the second conduction layer 202B, as depicted at test probe A.

In order to extract the charged carriers (e.g., electrons, holes, etc.) from the first conduction layer 202A and the second conduction layer 202B to charge the energy cell 106, rectifier bridge circuitry 220 is implemented to provide a same polarity of output with respect to reference ground for any input polarity (e.g., at a first input or second input). The first input of the rectifier bridge circuitry 220 is electrically coupled to the second conduction layer 202B and the second input of the rectifier bridge circuitry 220 is electrically coupled to the first conduction layer 202A. As depicted in FIG. 4A, a half-wave rectifier bridge 222 includes a first diode 226 connected in reverse bias across the second conduction layer 202B and a negative terminal (of the power collar 104 or the energy cell 106; the negative terminal being further electrically coupled to the female socket connector 105B of connection unit 105 at the edge of the photovoltaic collector 100) and an optional second diode 227 is connected in reverse bias across the first conduction layer 202A and a positive terminal (of the power collar 104 or the energy cell 106; the positive terminal being further electrically coupled to the male pin connector 105A of connection unit 105 at the edge of the photovoltaic collector 100). The half-wave rectifier bridge 222 of FIG. 4A coverts an AC power signal 410 at the input of the half-wave rectifier bridge 222 (at test probe A) from the plasma-sonic photovoltaic cell cross-section 200 to a pulsed DC power signal 412 at the output of the half-wave rectifier bridge 222 (at test probe B). In some examples, the energy cell 106 is electrically coupled across the output of the half-wave rectifier bridge 222 and the reference ground, thereby capturing and storing the oscillating charged carriers (e.g., electrons, holes, etc.) in the energy cell 106 for future use. In some configurations, the power collar 104 includes the rectifier bridge circuitry 220.

It should be appreciated that the rectifier bridge circuitry 220 can include one or more circuit elements to polarize the electric current. For example, the rectifier bridge circuitry 220 can be a full-wave rectifier bridge that includes four diodes interconnected so as to covert an AC power signal 410 (depicted at test probe A of FIG. 4B) of the plasma-sonic photovoltaic cell cross-section 200 to a pulsed DC power signal 412 (at test probe B of FIG. 4B). It should also be appreciated that capturing charged carriers (e.g., electrons, holes, etc.) along the surface of the nanoparticles for wavelengths of incident light longer than 700 nanometers causes a temperature of the first conduction layer 202A and the second conduction layer 202B to decrease because removing charged carriers (e.g., electrons, holes, etc.) from the plasma-sonic photovoltaic cell cross-section 200 extracts energy from the system that would otherwise contribute to heat. That is, removing oscillating charged carriers (e.g., electrons, holes, etc.) from the system slows down the overall motion of the molecules/atoms, which translates as reduced heat energy. This reduction of heat energy causes the adjacent layers that are thermally coupled to the first conduction layer 202A and the second conduction layer 202B to cool as well.

The plasmonic photovoltaic cell cross-section 225 depicted in FIG. 4B includes a first conduction layer 202A (e.g., first ultrastatic conducting layer), a diode layer 208, a plasmonic layer 204, and a second conduction layer 202B (e.g., second ultrastatic conducting layer). Both the first conductor layer 202A and the second conduction layer 202B can be made of a conductive material, such as metal, alloy, or a semiconductor (e.g., copper, aluminum, polysilicon, stainless steel, and the like). The first conductor layer 202A and/or the second conduction layer 202B can also made from a semimetal, such as graphene, arsenic, antimony, etc. In some examples, the first conductor layer 202A and/or the second conduction layer 202B is made from a semimetal (e.g., graphene, arsenic, antimony, etc.) that is p-doped or n-doped. In some configurations, the first conduction layer 202A is electrically coupled to the second conduction layer 202B.

In some configurations, the rectifier bridge circuitry 220 includes one or more diodes electrically coupled in series between the second conductor layer 202B and cathode of the energy cell 106 or power collar 104 and one or more diodes electrically coupled in series between the first conductor layer 202A and anode of the energy cell 106 or power collar 104, as depicted in FIG. 4A. In some configurations, the rectifier bridge circuitry 220 includes one or more diode layers electrically coupled to the plasmonic layer 204. For example, as depicted in the plasmonic photovoltaic cell cross-section 225 of FIG. 4B, a diode layer 208 is electrically coupled between the plasmonic layer 204 and the second conductor layer 202B. The diode layer 208 is a semiconductor layer with a p-doped portion adjacent to an n-doped portion to form a p-n junction. The p-n junction effectively replaces the first diode 226 of the plasmonic photovoltaic cell cross-section 200 depicted in FIG. 4A.

In some configurations, as shown in FIG. 4C, the rectifier bridge circuitry 220 includes a first diode layer 208A electrically coupled between the plasmonic layer 204 and the first conductor layer 202A (e.g., first ultrastatic conducting layer) and a second diode layer 208B electrically coupled between the plasmonic layer 204 and the second conductor layer 202B (e.g., second ultrastatic conducting layer). Both the first diode layer 208A and the second conductor layer 202B are semiconductor layers, each with a p-doped portion adjacent to an n-doped portion to form a p-n junction. As depicted in the plasmonic photovoltaic cell cross-section 250 of FIG. 4C, the p-n junction configuration of the first diode layer 208A effectively replaces the second diode 227 of the plasmonic photovoltaic cell cross-section 200 of FIG. 4A. As depicted in the plasmonic photovoltaic cell cross-section 250 of FIG. 4C, the p-n junction configuration of the second diode layer 208B effectively replaces the first diode 226 of the plasmonic photovoltaic cell cross-section 200 of FIG. 4A.

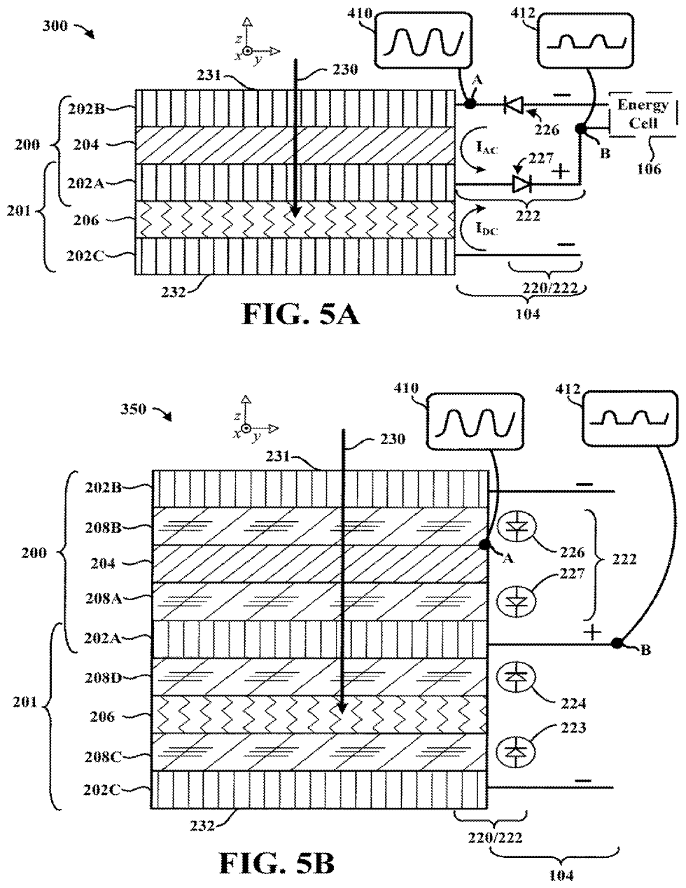

FIGS. 5A and 5B illustrate various cross-sectional views of exemplary hybrid plasmonic-based photovoltaic collectors. A hybrid plasmonic-based photovoltaic collector can include a plasmonic photovoltaic cell stacked (e.g., in parallel) with a photonic photovoltaic cell. For example, as depicted in FIG. 5A, the plasmonic photovoltaic cell cross-section 200 includes the plasmonic photovoltaic cell cross-section 200 (FIG. 4A) stacked (e.g., in parallel) with a photonic photovoltaic cell cross-section 201. The layout of the plasmonic photovoltaic cell cross-section 200 includes a first conduction layer 202A, a plasmonic layer 204, and a second conduction layer 202B as described supra. As described supra, first conduction layer 202A can be a transparent ultrastatic conducting layer (coated using ultrasonic coating technology utilizing ultrasonic spray nozzle) and second conduction layer can be a conventional conduction layer (e.g., transparent ITO layer).

The photonic photovoltaic cell cross-section 201 includes a photonic absorption layer 206 (e.g., photovoltaic layer) electrically coupled to the first conduction layer 202A (e.g., first ultrastatic conducting layer) and the third conduction layer 202C (e.g., third ultrastatic conducting layer). As depicted in FIG. 5A, the photonic absorption layer 206 is electrically coupled between the first conduction layer 202A and the third conduction layer 202C along a transverse direction (e.g., x-y plane). The photonic absorption layer 206 is configured to absorb incident light 230 shorter than a first wavelength of incident light and generates a first electric current along the first conduction layer 202A. The absorption of incident light 230 shorter than a first wavelength of incident light generates electron-hole pairs, which induces a direct electric current (e.g., a first electric current) that flows though the photonic absorption layer 206 from the third conduction layer 202C to the first conduction layer 202A. In some examples, the first electric current is a direct current (e.g., foe).

In some configurations, the photonic absorption layer 206 is a semiconductor, such as silicon (polycrystalline silicon or monocrystalline silicon), germanium, cadmium telluride, copper indium gallium selenide, gallium arsenide (GaAs), indium gallium arsenide, and the like. In some configurations the photonic photovoltaic cell implements quantum dots. Quantum dots are nano-sized semiconductor particles that are proportional in size to the absorption wavelength of incident light and can have a variety of shapes. For example, one or more quantum dots can have any one of a conical, rectangular, bi-pyramidal, tetrahedral, cubical, octahedral, cylindrical, ellipsoidal, or spherical shape. Such quantum dots can be made from a variety of semiconducting materials, such as CdS, CdSe, Sb₂S₃, PbS, etc. In some examples, the photonic absorption layer 206 is an organic such as a ruthenium metalorganic dye. In general, the size of quantum dots in the photonic absorption layer 206 is proportional to the first wavelength of incident light. As such, the first wavelength of incident light can be can be tuned by increasing or decreasing the size of each quantum dot. In some examples, the first wavelength of incident light is tuned longer than 700 nanometers, which corresponds to frequencies in the infrared spectrum. In some examples, the first wavelength is tuned shorter than 700 nanometers, which corresponds to frequencies in the visible light and ultra-violet spectrum.

As depicted in FIG. 5A, the surface of the plasmonic layer 204 is electrically coupled between the first conduction layer 202A and the second conduction layer 202B along an interface in a transverse direction (e.g., x-y plane). The plasmonic layer 204 can be made from an electrical insulator, a dielectric or a semiconductor. The plasmonic layer 204 can be a polymer or a ceramic. The plasmonic layer 204 can be polycarbonate. In general, the plasmonic layer 204 is non-conductive to direct current (e.g., IDc) but is conductive to alternating current (e.g., IAc). As such, plasmonic layer 204 is configured to be polarized in the presence of an electric field. This polarization causes positive charges to be displaced toward the electric field and negative charges to be displaced away from the electric field, which creates an internal electric field thereby reducing the overall electric field within the dielectric itself. The plasmonic layer 204 includes nanoparticles that couple with the polarization of the dielectric and induce charged carriers (e.g. electrons) to oscillate at a surface of the nanoparticles within the dielectric for certain (second) wavelengths of incident light. It should be appreciated that the induced electron oscillations occur throughout the dielectric and are not simply concentrated at an interface between the dielectric and an adjacent conduction layer (e.g., the first conduction layer 202A and the second conduction layer 202B). In some instances, the second wavelength of incident light is at a resonance wavelength of the oscillating charged carriers (e.g., electrons, holes, etc.).

The second wavelength of incident light that induces charged earners (e.g., electrons, holes, etc.) to oscillate at a surface of the nanoparticles correlates with the size of the nanoparticles within the plasmonic layer 204. As such, the second wavelength of incident light can be tuned by increasing or decreasing the size of the nanoparticles within plasmonic layer 204. In some examples, the second wavelength is tuned longer than 700 nanometers, which corresponds to frequencies in the infrared spectrum. In some examples, the second wavelength of incident light is tuned shorter than 700 nanometers, which corresponds to frequencies in the visible light and ultra-violet spectrum. In some examples, the first wavelength of the incident light is tuned longer than the second wavelength of the incident light. In some examples, the first wavelength of the incident light is tuned shorter than the second wavelength of the incident light.

In some examples, the plasmonic layer 204 is an electrical insulator. In some examples, the plasmonic layer 204 is a dielectric with a complex dielectric constant. In some examples, the nanoparticles contribute to the plasmonic layer 204 having a complex dielectric constant. The nanoparticles within the plasmonic layer 204 can be homogenously dispersed (e.g., mixed) throughout the plasmonic layer 204 and can be a dielectric, a semiconductor, a semimetal, or a metal. The shape of the nanoparticles can be substantially similar or vary. The shape can have any one of a conical, rectangular, bi-pyramidal, tetrahedral, cubical, octahedral, cylindrical, ellipsoidal, or spherical shape. In some examples, the dielectric nanoparticles are dielectric particles suspended in a polymer matrix. In some examples, the dielectric nanoparticles are dielectric particles suspended in a polycarbonate. In some examples, the dielectric nanoparticles are dielectric particles suspended in a ceramic matrix.

As depicted in FIG. 5A, the surface of the second conduction layer 202B (e.g., second ultrastatic conducting layer) is electrically coupled to the plasmonic layer 204 along an interface in a transverse direction (e.g., x-y plane). This configuration facilitates capturing the oscillation of charged carriers (e.g., electrons, holes, etc.) of the nanoparticles in the plasmonic layer 204 at the second conduction layer 202B to generate a second electric current along the second conduction layer 202B. In some examples, the second electric current is an alternating current (e.g., IAc), as depicted at test probe A in FIG. 5A.

In order to extract the charged carriers (e.g., electrons, holes, etc.) from the second conduction layer 202B to charge the energy cell 106, a rectifier bridge circuitry 220 is implemented to provide a same polarity of output of the rectifier bridge circuitry 220 with respect to reference ground for any input polarity (e.g., at a first input or second input). The first input of the rectifier bridge circuitry 220 is electrically coupled to the second conduction layer 202B, and the second input of the rectifier bridge circuitry 220 is electrically coupled to the first conduction layer 202A. Notably, a pulsed direct current (e.g., IDc) is provided at an output of the rectifier bridge circuitry 220 (e.g., at test probe B). As depicted in FIG. 5A, the first conduction layer 202A is electrically coupled to an input of the rectifier bridge circuitry 220.

As depicted in FIG. 5A, a half-wave rectifier bridge 222 includes a first diode 226 connected in reverse bias across the second conduction layer 202B and a negative terminal (of the power collar 104 or the energy cell 106; the negative terminal being further electrically coupled to the female socket connector 105B of connection unit 105 at the edge of the photovoltaic collector 100 corresponding to FIG. 5A) and an optional second diode 227 connected in reverse bias across the first conduction layer 202A and a positive terminal (of the power collar 104 or the energy cell 106; the positive terminal being further electrically coupled to the male pin connector 105A of connection unit 105 at the edge of the photovoltaic collector 100 corresponding to FIG. 5A). The half-wave rectifier bridge 222 of FIG. 5A coverts an AC power signal 410 at the input of the half-wave rectifier bridge 222 (at test probe A) from the plasmonic photovoltaic cell cross-section 200 to a pulsed DC power signal 412 at the output of the half-wave rectifier bridge 222 (at test probe B). In some examples, the energy cell 106 is electrically coupled across the output of the half-wave rectifier bridge 222 and the reference ground, thereby capturing and storing the oscillating charged carriers (e.g., electrons, holes, etc.) in the energy cell 106 for future use.

It should be appreciated that the half-wave rectifier bridge 222 can be a full-wave rectifier bridge that includes four diodes interconnected so as to covert an AC power signal 410 (depicted at test probe A of FIG. 5A) from the hybrid plasmonic photovoltaic cell cross-section 300 to a pulsed DC power signal 412. It should also be appreciated that capturing charged carriers (e.g., electrons, holes, etc.) along the surface of the nanoparticles for wavelengths of incident light longer than 700 nanometers causes a temperature of the first conduction layer 202A and the second conduction layer 202B to decrease because removing charged carriers (e.g., electrons, holes, etc.) from the plasmonic photovoltaic cell cross-section 200 extracts energy from the system that would otherwise contribute to heat. That is, removing oscillating charged carriers (e.g., electrons, holes, etc.) from the system slows down the overall motion of the molecules/atoms, which translates as reduced heat energy. This reduction of heat energy causes the adjacent layers that are thermally coupled to the first conduction layer 202A and the second conduction layer 202B to cool as well. In this instance, the photonic absorption layer 206 is thermally coupled to the first conduction layer 202A and causes the photonic absorption layer 206 to cool. The cooling of the photonic absorption layer 206 by the second conduction layer 202A increases the efficiency of the photonic absorption layer 206 since the quantum efficiency increases with lower temperature.

In general, the second conduction layer 202B and the plasmonic layer 204 are translucent or transparent to wavelengths longer than 700 nanometers, thereby providing an optical path for incident light 230 to be absorbed by the photonic absorption layer 206. As such, both the direct current (e.g., a first electric current, IDc) from the electron-hole generations of the photonic absorption layer 206 and the alternating current (e.g., second electric current, IAc) captured from the oscillating charged carriers (e.g., electrons, holes, etc.) from the plasmonic layer 204 can provide electrical energy to the energy cell 106 in parallel with each other.

In some examples, each layer (e.g., the second conduction layer 202B, the plasmonic layer 204, and the photonic absorption layer 206, etc.) are translucent or transparent to the incident light within the visible spectrum (e.g., 390 nanometers to 700 nanometers) at a zero-degree incident angle. In some examples, a combination of each layer (e.g., the second conduction layer 202B, the plasmonic layer 204, and the photonic absorption layer 206, etc.) has a transmittance of light within the visible spectrum greater than 0.76 at a zero-degree incident angle. In some examples, the photonic absorption layer 206 includes light scattering particles. In some examples, currents (e.g., a first electric current and second electric current) are superimposed.

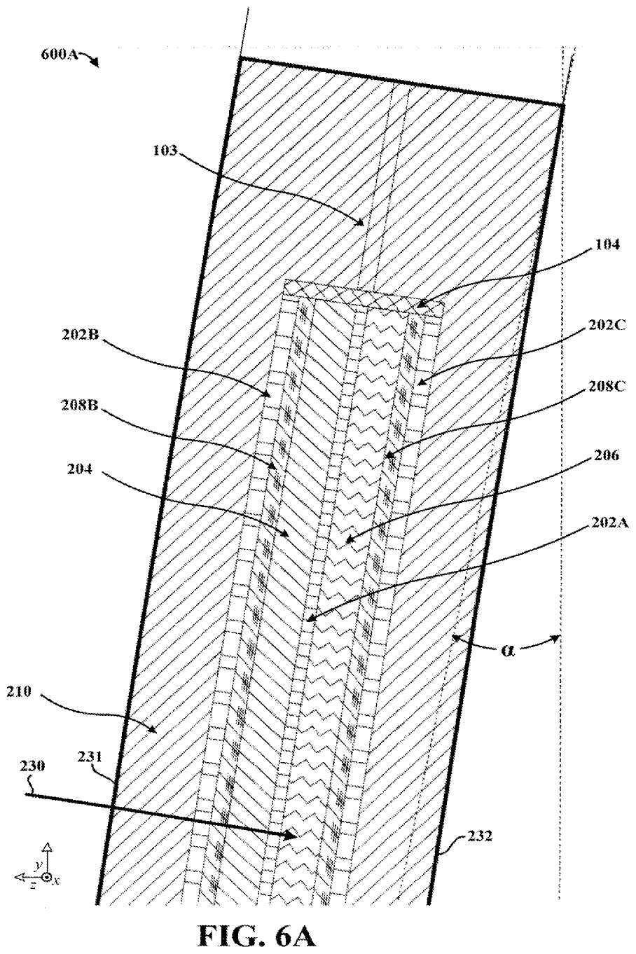

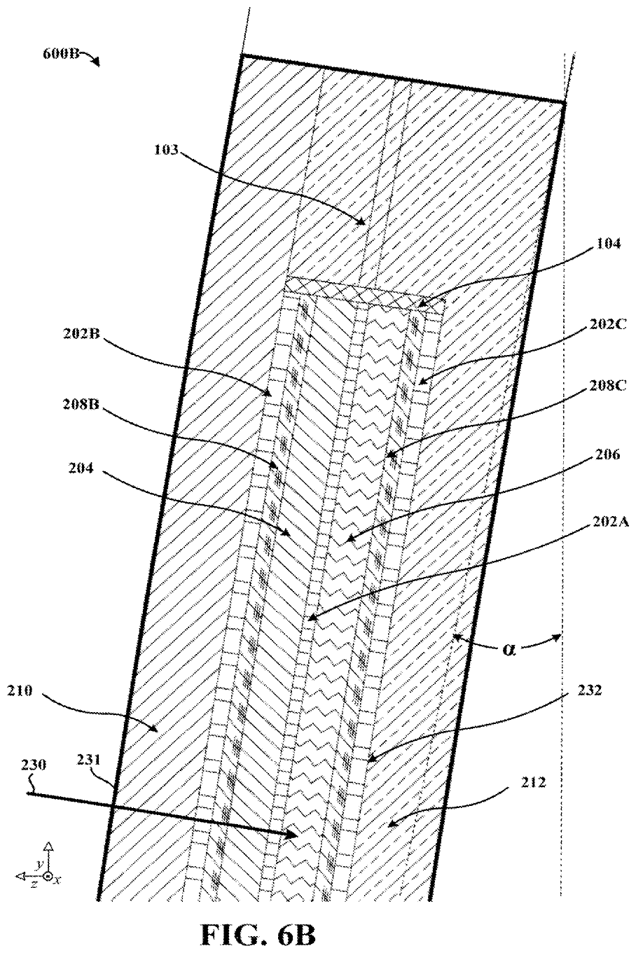

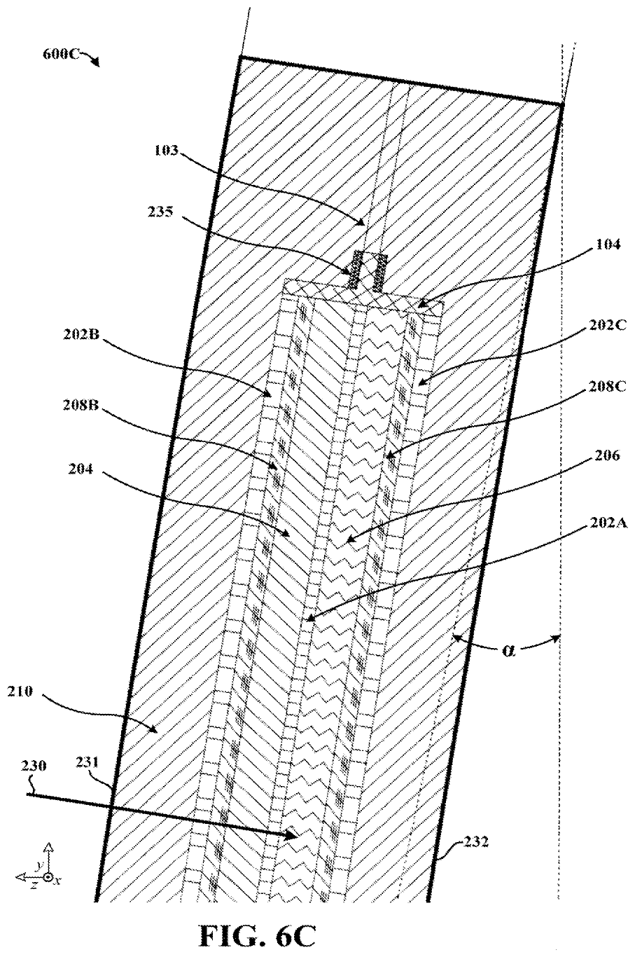

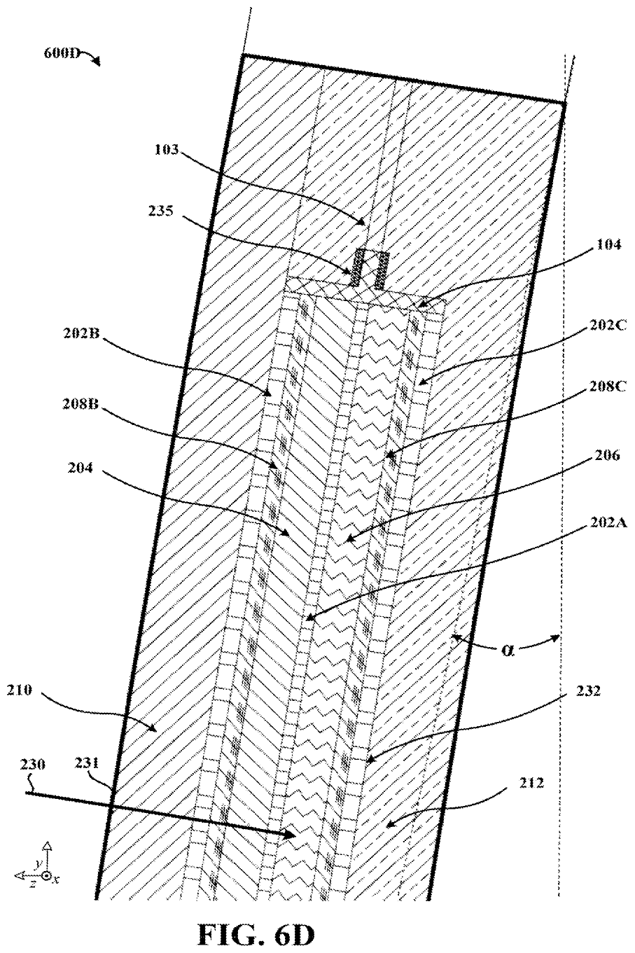

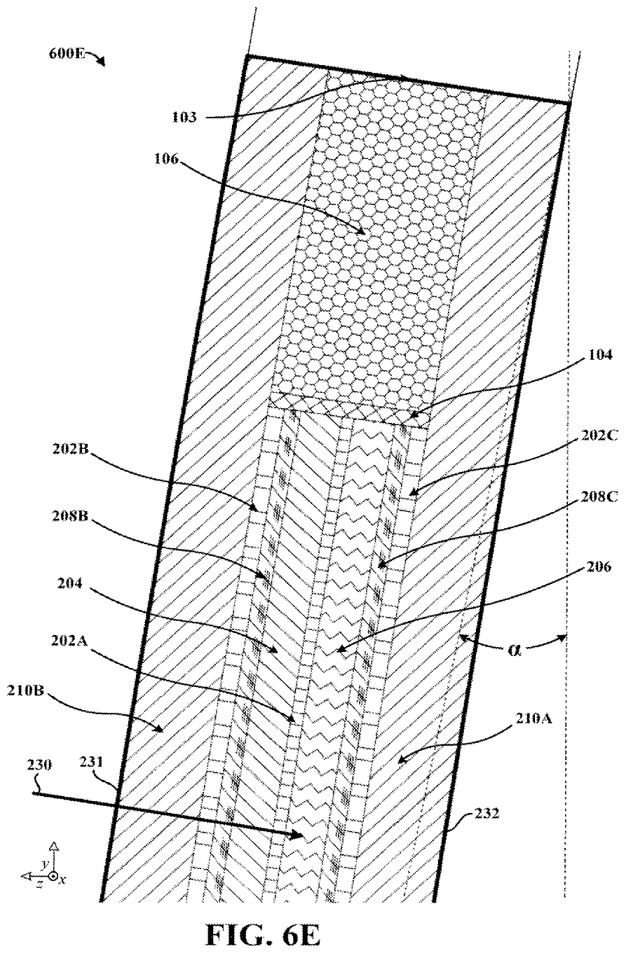

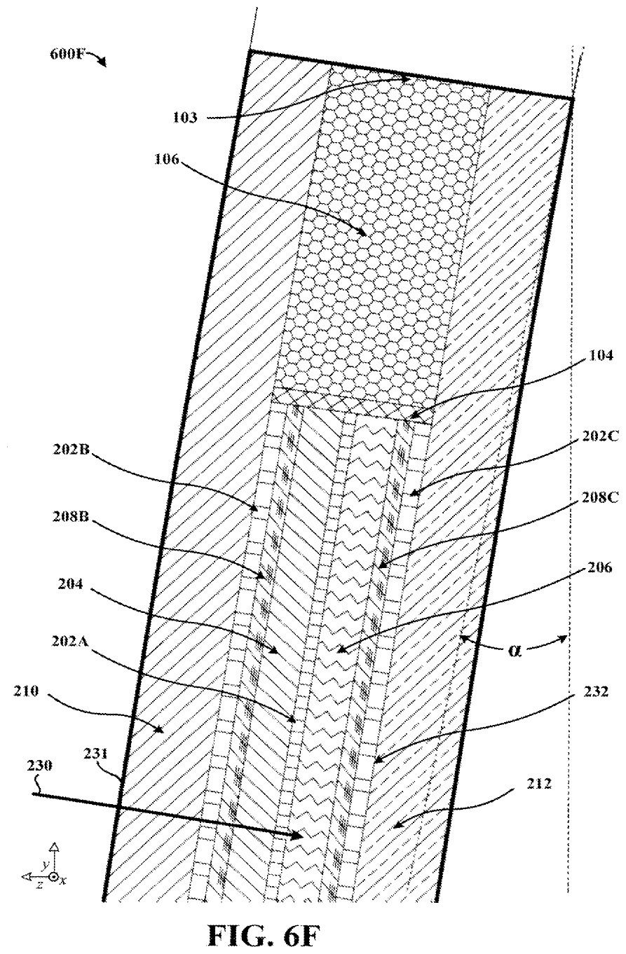

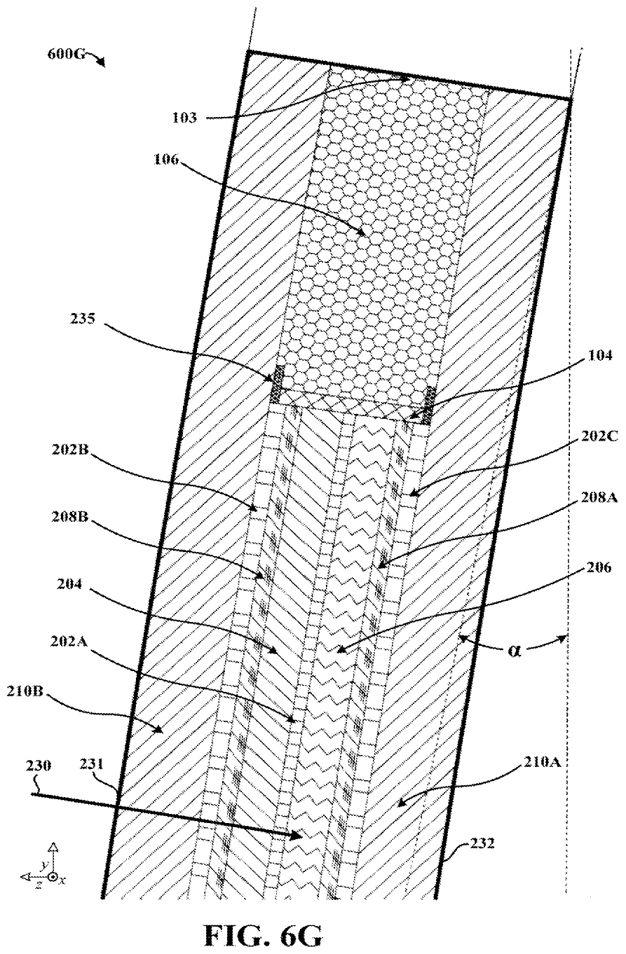

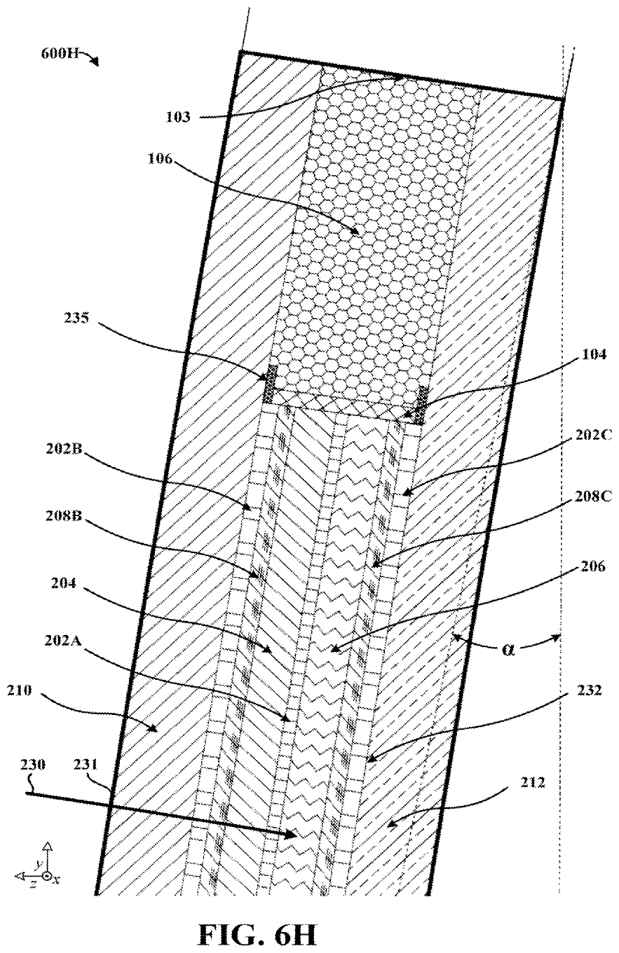

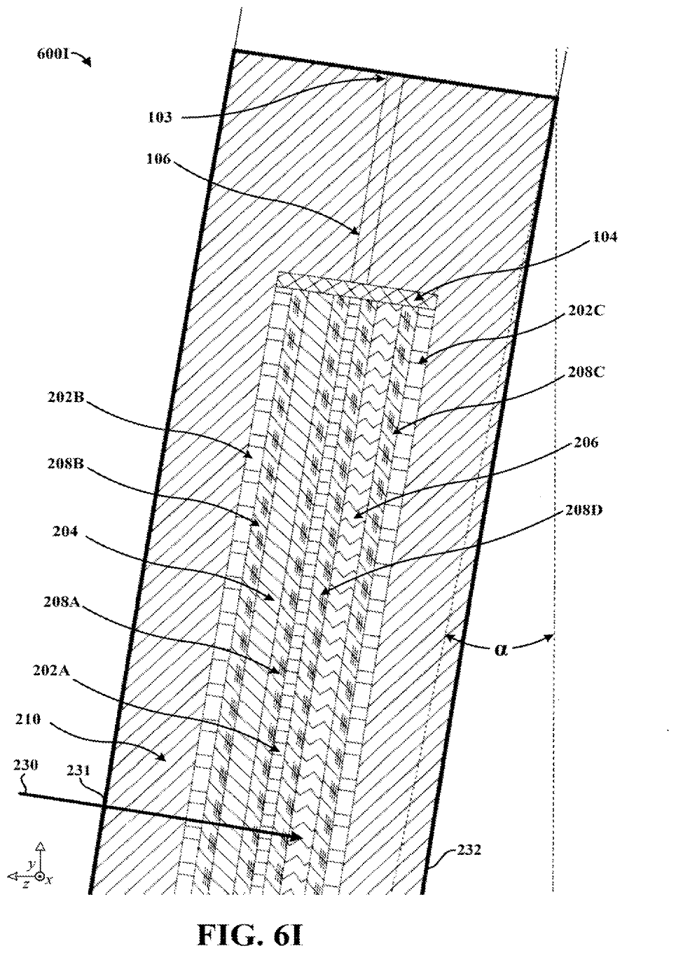

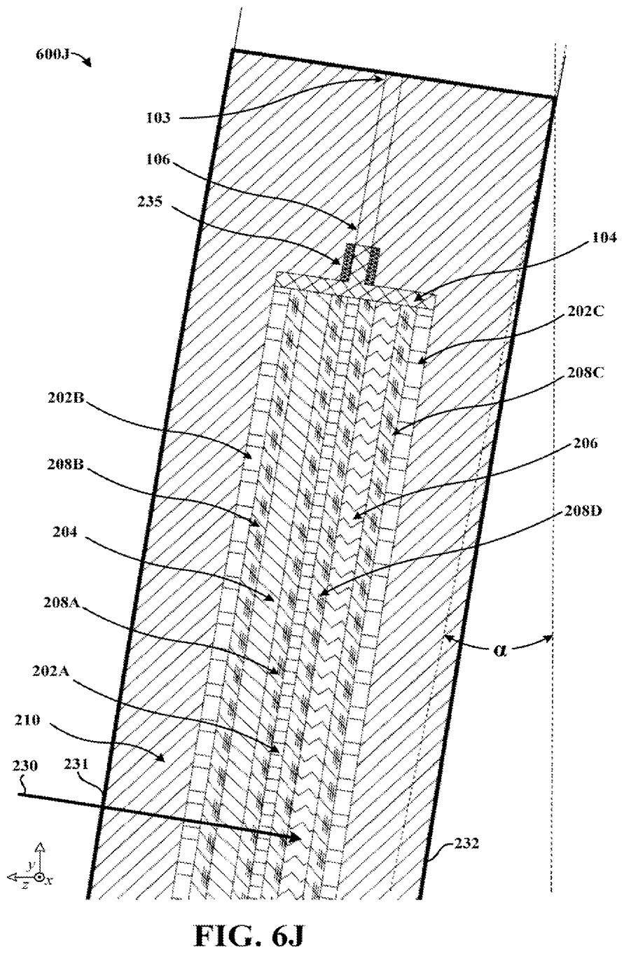

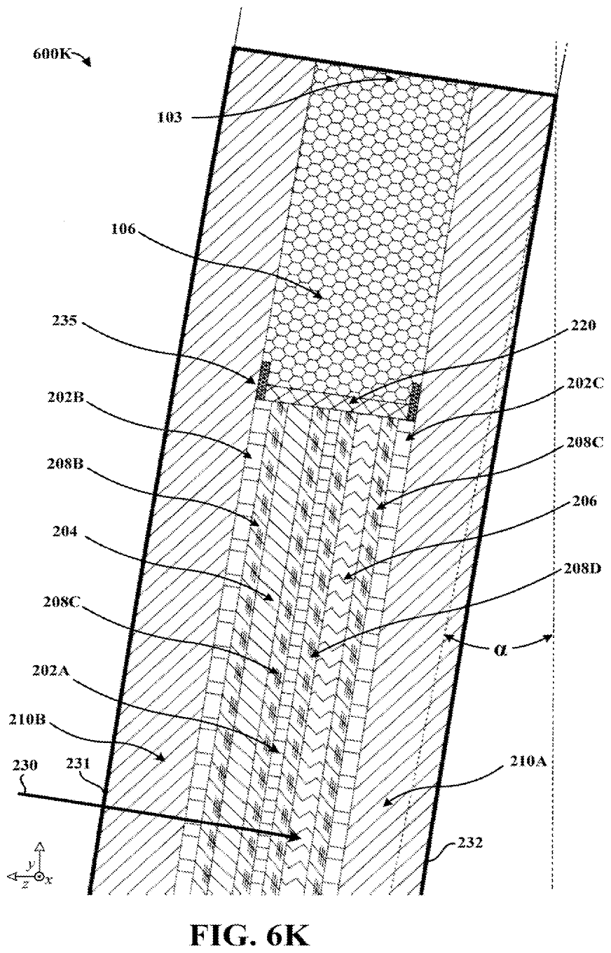

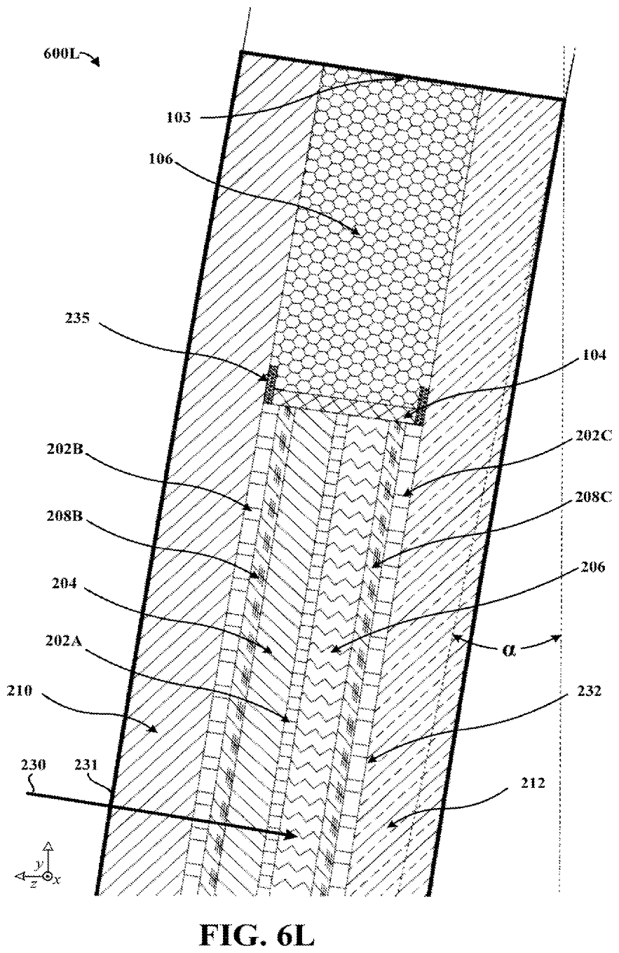

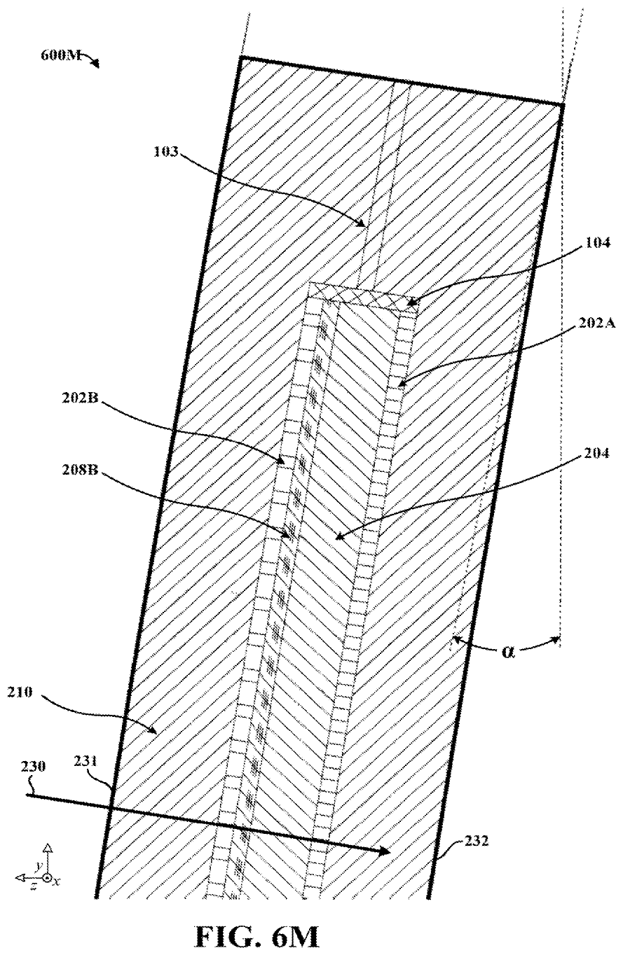

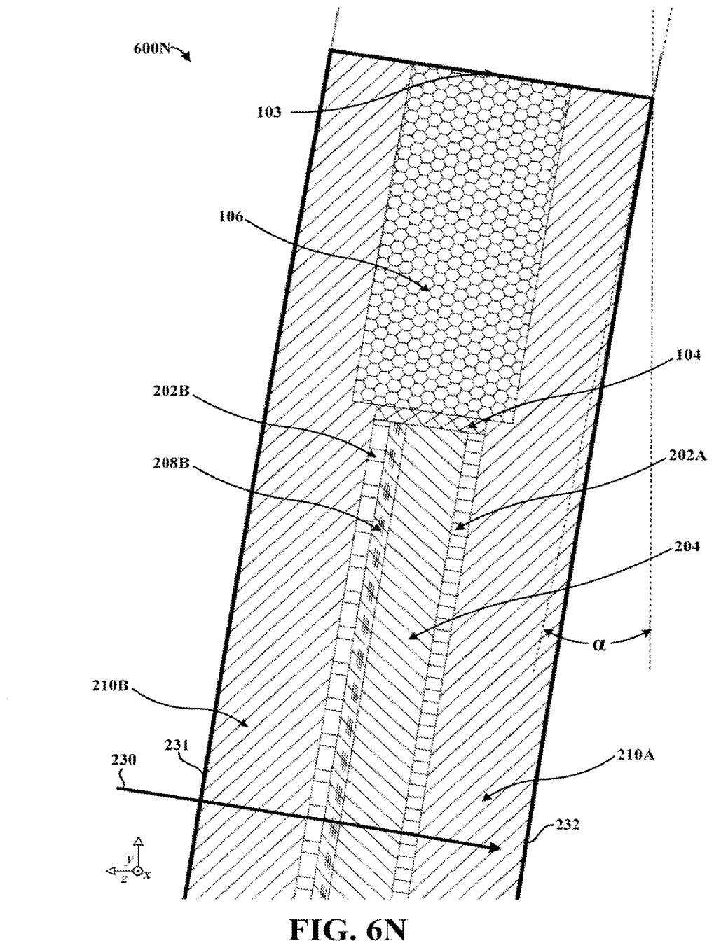

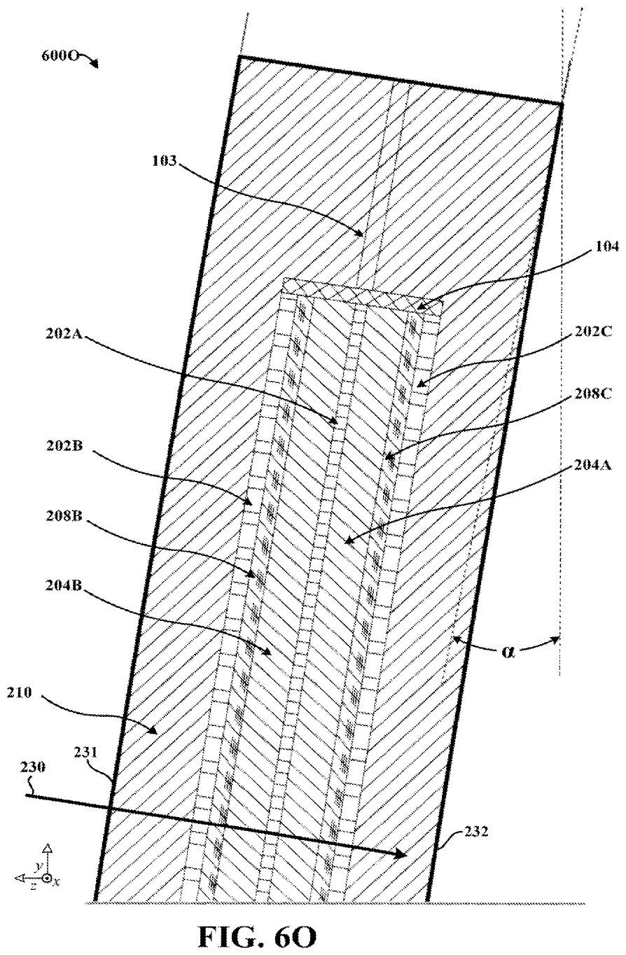

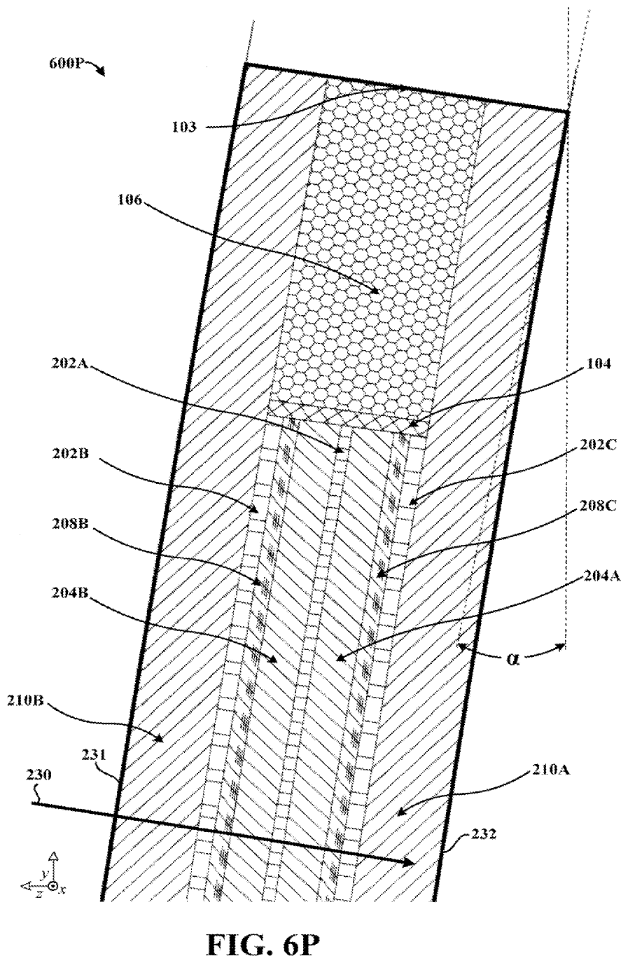

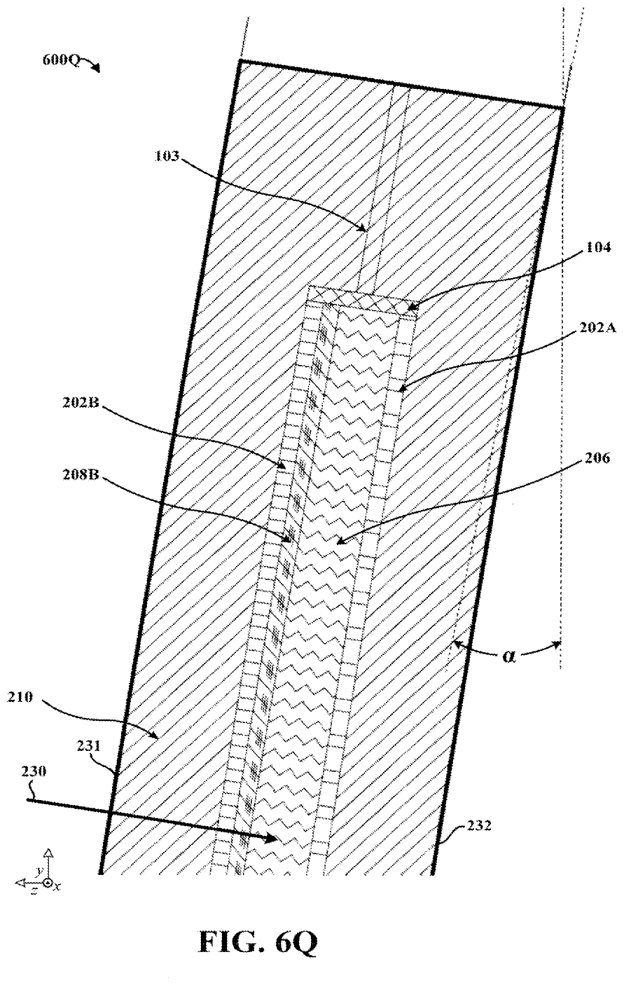

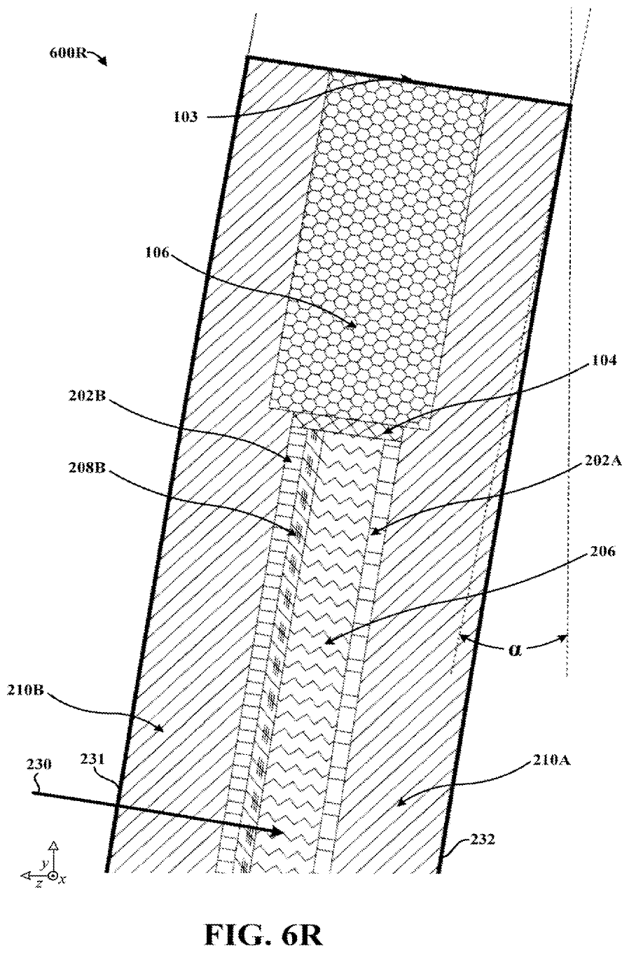

In some examples, one or more translucent layers are provided as a substrate around the first conduction layer 202A, the photonic absorption layer 206, the plasmonic layer 204, and the second conduction layer 202B (FIGS. 6A-6R). In some configurations, the one or more translucent layers are configured to hermetically seal the third conduction layer 202C (e.g., third ultrastatic conducting layer), the photonic absorption layer 206, the first conduction layer 202A (e.g., first ultrastatic conducting layer), the plasmonic layer 204, and the second conduction layer 202B. In some examples, a reflector is provided adjacent the third conduction layer 202C on a distal surface 232 of incident light 230. In such a configuration, the reflector is configured to reflect incident light 230 back through the third conduction layer 202C, the photonic absorption layer 206, the first conduction layer 202A, the plasmonic layer 204, and the second conduction layer 202B to increase chances of absorption and increase induced charged carriers (e.g., electrons, holes, etc.) oscillations at a surface of the nanoparticles. The reflector can be made from a metal, such as aluminum, silver, gold, copper, etc. In some configurations, the reflector layer 212 (e.g., FIG. 6B) is a composite material that includes a metal reflection layer. In some instances, the metal reflection layer is configured to reflect heat. In some examples, the reflector layer 212 is a thermal barrier. In some instances, the reflector layer 212 is a thermal insulator.

In some configurations, the half-wave rectifier bridge 222 includes a first diode layer 208A electrically coupled between the plasmonic layer 204 and the first conductor layer 202A (e.g., first ultrastatic conducting layer). For example, as depicted in the enhanced hybrid plasmonic photovoltaic cell cross-section 350 of FIG. 5B, the p-n junction configuration of the first diode layer 208A effectively replaces the second diode 227 of the hybrid plasmonic photovoltaic cell cross-section 300 of FIG. 5A. In such a configuration the first diode layer 208A is configured to direct charged carriers (e.g., electrons, holes, etc.) to be captured by the first conducting layer 202A. In some configurations, the half-wave rectifier bridge 222 includes a second diode layer 208B electrically coupled between the plasmonic layer 204 and the second conductor layer 202B. For examples, as depicted in the enhanced hybrid plasmonic photovoltaic cell cross-section 350 of FIG. 5B, the p-n junction configuration of the second diode layer 208B effectively replaces the first diode 226 of the hybrid plasmonic photovoltaic cell cross-section 300 of FIG. 5A. In such a configuration, the second diode layer 208B is configured to direct charged carriers (e.g., electrons, holes, etc.) to be captured by the second conducting layer 202B. Both the first diode layer 208A and the second conductor layer 202B are semiconductor layers, each with a p-doped portion adjacent to an n-doped portion to form a p-n junction.

In some configurations, photonic photovoltaic cell cross-section 201 includes a third diode layer 208C electrically coupled between the photonic absorption layer 206 and the third conductor layer 202C (e.g., third ultrastatic conducting layer). The third diode layer 208C is a semiconductor layer with a p-doped portion adjacent to an n-doped portion to form a p-n junction. As depicted in FIG. 5B, the third diode layer 208C essentially forms a third diode 223 in reverse bias across third conduction layer 202C and the photonic absorption layer 206. In such a reverse bias configuration, the built-in potential of the p-n junction of the third diode layer 208C directs charged carriers (e.g., electrons, holes, etc.) to be captured by the third conducting layer 202C.

In some configurations, photonic photovoltaic cell cross-section 201 includes a fourth diode layer 208D electrically coupled between the photonic absorption layer 206 and the first conductor layer 202A (e.g., first ultrastatic conducting layer). The fourth diode layer 208D is a semiconductor layer with a p-doped portion adjacent to an n-doped portion to form a p-n junction. As depicted in FIG. 5B, the fourth diode layer 208D essentially forms a fourth diode 224 in reverse bias across first conduction layer 202A and the photonic absorption layer 206. In such a reverse bias configuration, the built-in potential of the p-n junction of the fourth diode layer 208D directs charged carriers (e.g., electrons, holes, etc.) to be captured by the first conducting layer 202A.

In general, the second conduction layer 202B, the second diode layer 208B, the plasmonic layer 204, and the first diode layer 208A are translucent or transparent to wavelengths longer than 700 nanometers, thereby providing an optical path for incident light 230 to be absorbed by the photonic absorption layer 206. As such, both the direct current (e.g., a first electric current, IDc) from the electron-hole generations of the photonic absorption layer 206 and the alternating current (e.g., second electric current, IAc) captured from the oscillating charged carriers (e.g., electrons, holes, etc.) in plasmonic layer 204 can provide electrical energy to the energy cell 106 in parallel with each other.

In some examples, each layer (e.g., the second conduction layer 202B, the second diode layer 208B, the plasmonic layer 204, the first diode layer 208A, the first conduction layer 202A, the fourth diode layer 208D, the photonic absorption layer 206, the third diode layer 208C, and the third conduction layer 202C, etc.) are translucent or transparent to the incident light within the visible spectrum (e.g., 390 nanometers to 700 nanometers) at a zero degree incident angle. In some examples, a combination of each layer (e.g., the second conduction layer 202B, the second diode layer 208B, the plasmonic layer 204, the first diode layer 208A, the first conduction layer 202A, the fourth diode layer 208D, the photonic absorption layer 206, the third diode layer 208C, and the third conduction layer 202C, etc.) has a transmittance of light within the visible spectrum greater than 0.76 at a zero degree incident angle. In some examples, the photonic absorption layer 206 includes light-scattering particles. In some examples, currents (e.g., a first electric current and second electric current) are superimposed by having the second conduction layer 202B electrically coupled to the third conduction layer 202C.

In some examples, one or more translucent layers are provided as a substrate around the second conduction layer 202B, the second diode layer 208B, the plasmonic layer 204, the first diode layer 208A, the first conduction layer 202A, the fourth diode layer 208D, the photonic absorption layer 206, the third diode layer 208C, and the third conduction layer 202C, (FIGS. 6A-6R). In some configurations, the one or more translucent layers are configured to hermetically seal the second conduction layer 202B, the second diode layer 208B, the plasmonic layer 204, the first diode layer 208A, the first conduction layer 202A, the fourth diode layer 208D, the photonic absorption layer 206, the third diode layer 208C, and the third conduction layer 202C.

In some configurations, a reflector layer 212 (e.g., FIG. 6B) is provided on a distal surface 232 of incident light 230. In such a configuration, the reflector layer 212 is configured to reflect incident light 230 back through the second conduction layer 202B, the second diode layer 208B, the plasmonic layer 204, the first diode layer 208A, the first conduction layer 202A, the fourth diode layer 208D, the photonic absorption layer 206, the third diode layer 208C, and the third conduction layer 202C to increase chances of absorption and increase induced charged carrier (e.g., electrons, holes, etc.) oscillations at a surface of the nanoparticles. The reflector layer 212 can be a metal layer, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

FIGS. 6A-6R illustrate cross-sectional views of various plasmonic-based and/or photonic based photovoltaic collectors. A first enhanced hybrid plasmonic photovoltaic collector cross-section 600A depicted in FIG. 6A includes the translucent layer 210 surrounding the third conduction layer 202C, the third diode layer 208C, the photonic absorption layer 206, the first conduction layer 202A, the plasmonic layer 204, the second diode layer 208B, the second conduction layer 202B, the power collar 104, and interconnect traces 103. The first enhanced hybrid plasmonic photovoltaic collector cross-section 600A has a convex shape, where the photovoltaic collector is elongated toward an incident surface 231 of incident light 230, with a largest angle of curvature, α, at the edges of the photovoltaic collector.

The functionality of the first enhanced hybrid plasmonic photovoltaic collector cross-section 600A includes one or more layers of the enhanced hybrid plasmonic photovoltaic cell cross-section 350 (FIG. 5B), as described supra. The layers include the third conduction layer 202C, the third diode layer 208C, the photonic absorption layer 206, the first conduction layer 202A, the plasmonic layer 204, the second diode layer 208B, and the second conduction layer 202B. The interconnect traces 103 can be made from a conductive material, such as copper, aluminum, polysilicon, stainless steel, graphene, and the like. Portions of interconnect traces 103 are hermetically sealed within the translucent layer 210. The interconnect traces 103 are configured to provide electrical conduits to the anode of the power collar 104 and the cathode of the power collar 104. In some configurations, the interconnect traces 103 are connected to a socketing feature, such as a male or a female connector that is configured to connect (e.g., electrically couple) with adjacent photovoltaic collectors. In some configurations, the interconnect traces 103 are a part of the power collar 104. The socketing feature connected to interconnect traces 103 is described supra in connection with FIGS. 1A, 12A-12D, and 13. That is, interconnect traces 103 may provide electrical conduits from the positive terminal (anode) of power collar 104 (or energy cell 106) and the negative terminal (cathode) of power collar 104 (or energy cell 106), to one or more connection units 105, such that the positive terminal (anode) of power collar 104 is connected to male pin connector 105A and the negative terminal (cathode) of power collar 104 is connected to female socket connector 105B, at the edge of photovoltaic collector 100 (FIGS. 1A, 12A-12D, and 13). Functional aspects of the rectifier bridge circuitry 220 are described supra. The rectifier bridge circuitry 220 can be hermetically sealed within the translucent layer 210 or can be electrically coupled external the translucent layer 210 via the interconnect traces 103. In some configurations, the rectifier bridge circuitry 220 is a full-wave rectifier. In some configurations, the rectifier bridge circuitry 220 is a half-wave rectifier 222 with one or more diodes, as depicted in any one of FIGS. 4A-4C.

The power collar 104 is situated around a periphery of the first enhanced hybrid plasmonic photovoltaic collector cross-section 600A. The power collar 104 is configured to direct charged carriers (e.g., electrons, holes, etc.) to an energy cell or inverter or to adjacent collectors 100 via one or more connection units 105. The power collar 104 is made from semiconductor materials, such as silicon (polycrystalline silicon or monocrystalline silicon), germanium, cadmium telluride, copper indium gallium selenide, gallium arsenide (GaAs), indium gallium arsenide, and the like. In some configurations, the power collar 104 includes the rectifier bridge circuitry 220. In some configurations, the power collar 104 is configured to electrically couple with one or more adjacent photovoltaic collectors via connection units 105. For instance, the power collar 104 can include a male or a female socketing feature (see FIGS. 1A, 12A-12D, and 13) to connect (e.g., electrically couple) with adjacent photovoltaic collectors.

The translucent layer 210 envelopes the third conduction layer 202C, the third diode layer 208C, the photonic absorption layer 206, the first conduction layer 202A, the plasmonic layer 204, the second diode layer 208B, and the second conduction layer 202B. The translucent layer 210 can optionally envelop or partially envelop the interconnect traces 103, the rectifier bridge circuitry 220, and the power collar 104 and one or more connection units 105 (not shown in FIG. 6A).

The translucent layer 210 provides a hermetic seal to protect the photovoltaic cell from the elements (e.g., rain, snow, wind, dust, etc.). The translucent layer 210 also provides structural support to protect the photovoltaic cell from impact damage (e.g., hail, rocks, sand, etc.). The translucent layer 210 can be made from any material that is translucent or transparent to wavelength longer than 700 nanometers, thereby providing an optical path for incident light 230 in the infrared spectrum to be absorbed by the photonic absorption layer 206. The translucent layer 210 can be made from any material that is translucent or transparent to wavelength shorter than 700 nanometers, thereby providing an optical path for incident light 230 in the visible or ultraviolet spectrum to be absorbed by the photonic absorption layer 206. In some examples, the translucent layer 210 is made from any material that is translucent or transparent in regions that span portions of both the infrared, visible, and ultraviolet spectrum. In some examples, translucent layer 210 is a polymer or a ceramic.

In some examples, the first enhanced hybrid plasmonic photovoltaic collector cross-section 600A is translucent or transparent such that some incident light 230 passes through the first enhanced hybrid plasmonic photovoltaic collector cross-section 600A and exits from a distal surface 232 of incident light 230.

FIG. 6B depicts a second enhanced hybrid plasmonic photovoltaic collector cross-section 600B that is a variant of the first enhanced hybrid plasmonic photovoltaic collector cross-section 600A. The second enhanced hybrid plasmonic photovoltaic collector cross-section 600B includes the translucent layer 210 adjacent the second conduction layer 202B along an incident surface 231 of incident light 230 and a reflector layer 212 provided adjacent the first conduction layer 202A along a distal surface 232 of incident light 230. The translucent layer 210 and the reflector layer 212 sandwich one or more layers of the enhanced hybrid plasmonic photovoltaic cell cross-section 350 (FIG. 5B), such as the third conduction layer 202C, the third diode layer 208C, the photonic absorption layer 206, the first conduction layer 202A, the plasmonic layer 204, the second diode layer 208B, the second conduction layer 202B, the power collar 104, and interconnect traces 103. One or more optional layers can be included, such as the third diode layer 208C, fourth diode layer 208D, etc. The functionality of the second enhanced hybrid plasmonic photovoltaic collector cross-section 600B includes one or more layers of the enhanced hybrid plasmonic photovoltaic cell cross-section 350, as described supra with respect to FIG. 5B and FIG. 6A. Functional aspects of additional layers, which can include the interconnect traces 103, the rectifier bridge circuitry 220, and the power collar 104, are also described supra with respect to FIG. 5B and FIG. 6A. The second enhanced hybrid plasmonic photovoltaic collector cross-section 600B has a convex shape, where the photovoltaic collector is elongated toward an incident surface 231 of incident light 230, with a largest angle of curvature, α, at the edges of the photovoltaic collector.

The reflector 212 is configured to reflect incident light 230 back through the third conduction layer 202C, the third diode layer 208C, the photonic absorption layer 206, the first conduction layer 202A, the plasmonic layer 204, the second diode layer 208B, and the second conduction layer 202B to increase chances of absorption and increase induced charged carrier (e.g., electrons, holes, etc.) oscillations at a surface of the nanoparticles. In some configurations, the reflector layer 212 includes an electrical insulation layer to insulate the reflector layer 212 from the other layers. In some configurations, the reflector layer 212 is made from a metal, such as aluminum, silver, gold, copper, etc. In some configurations, the reflector layer 212 is a composite material that includes a metal reflection layer. In some instances, the metal reflection layer is configured to reflect heat In some examples, the reflector layer 212 is a thermal barrier. In some instances, the reflector layer 212 is a thermal insulator.

FIG. 6C depicts a third enhanced hybrid plasmonic photovoltaic collector cross-section 600C that is a variant of the first enhanced hybrid plasmonic photovoltaic collector cross-section 600A. The third enhanced hybrid plasmonic photovoltaic collector cross-section 600C includes the translucent layer 210 surrounding the third conduction layer 202C, the third diode layer 208C, the photonic absorption layer 206, the first conduction layer 202A, the plasmonic layer 204, the second diode layer 208B, the second conduction layer 202B, the power collar 104, and interconnect traces 103. One or more optional layers can be included, such as the third diode layer 208C, fourth diode layer 208D, etc. The third enhanced hybrid plasmonic photovoltaic collector cross-section 600C has a convex shape, where the photovoltaic collector is elongated toward an incident surface 231 of incident light 230, with a largest angle of curvature, α, at the edges of the photovoltaic collector. The functionality of the third enhanced hybrid plasmonic photovoltaic collector cross-section 600C includes one or more layers of the enhanced hybrid plasma-sonic photovoltaic cell cross-section 350, as described supra with respect to FIG. 5B and FIG. 6A. Functional aspects of additional layers, which can include the interconnect traces 103, the rectifier bridge circuitry 220, and the power collar 104, are also described supra with respect to FIG. 5B and FIG. 6A.

The rectifier bridge circuitry 220 further includes light-emitting diodes (LEDs) 235. In some examples, the rectifier bridge circuitry 220 is configured to illuminate the LEDs 235 when the power is being delivered to the energy cell 106 (and/or to adjacent one or more photovoltaic collectors 100 via respective one or more connection units 105). In some examples, the rectifier bridge circuitry 220 is configured to illuminate the LEDs 235 when the power is not being delivered to the energy cell 106 (and/or to adjacent one or more photovoltaic collectors 100 via respective one or more connection units 105). In some examples, the rectifier bridge circuitry 220 is configured to illuminate the LEDs 235 at night as a backlight illumination to a building/structure/transportation/walkway. In some instances, the LEDs 235 are high intensity LEDs.

FIG. 6D depicts a fourth enhanced hybrid plasmonic photovoltaic collector cross-section 600D that is a variant of the first enhanced hybrid plasmonic photovoltaic collector cross-section 600A. The fourth enhanced hybrid plasmonic photovoltaic collector cross-section 600D includes the translucent layer 210 adjacent the second conduction layer 202B along an incident surface 231 of incident light 230 and a reflector layer 212 provided adjacent the first conduction layer 202A along a distal surface 232 of incident light 230.

The translucent layer 210 and the reflector layer 212 sandwich one or more layers of the enhanced hybrid plasmonic photovoltaic cell cross-section 350 (FIG. 5B), such as the third conduction layer 202C, the third diode layer 208C, the photonic absorption layer 206, the first conduction layer 202A, the plasmonic layer 204, the second diode layer 208B, the second conduction layer 202B, the power collar 104, and interconnect traces 103. One or more optional layers can be included, such as the third diode layer 208C, fourth diode layer 208D, etc. The fourth enhanced hybrid plasmonic photovoltaic collector cross-section 600D has a convex shape, where the photovoltaic collector is elongated toward an incident surface 231 of incident light 230, with a largest angle of curvature, α, at the edges of the photovoltaic collector. The functionality of the fourth enhanced hybrid plasmonic photovoltaic collector cross-section 600D includes one or more layers of the enhanced hybrid plasmonic photovoltaic cell cross-section 350, as described supra with respect to FIG. 5B and FIGS. 6A-6C. Functional aspects of additional layers, which can include the interconnect traces 103, the rectifier bridge circuitry 220, and the power collar 104, are also described supra with respect to FIG. 5B and FIGS. 6A-6C.

The reflector layer 212 is provided adjacent the first conduction layer 202A along a distal surface 232 of incident light 230. In such a configuration, the reflector layer 212 is configured to reflect incident light 230 back through the third conduction layer 202C, the third diode layer 208C, the photonic absorption layer 206, the first conduction layer 202A, the plasma-sonic layer 204, the second diode layer 208B, and the second conduction layer 202B to increase chances of absorption and increase induced charged carriers (e.g., electrons, holes, etc.) oscillations at a surface of the nanoparticles. In some configurations, the reflector layer 212 includes an electrical insulation layer to insulate the reflector layer 212 from the layers. In some configurations, the reflector layer 212 is made from a metal, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

FIG. 6E depicts a fifth enhanced hybrid plasmonic photovoltaic collector cross-section 600E that is a variant of the first enhanced hybrid plasmonic photovoltaic collector cross-section 600A. The fifth enhanced hybrid plasmonic photovoltaic collector cross-section 600E includes a first translucent layer 210A provided adjacent the first conduction layer 202A along a distal surface 232 of incident light 230 and a second translucent layer 210B adjacent the second conduction layer 202B along an incident surface 231 of incident light 230.

The first translucent layer 210A and the second translucent layer 210B sandwich one or more layers of the enhanced hybrid plasmonic photovoltaic cell cross-section 350 (FIG. 5B), such as the third conduction layer 202C, the third diode layer 208C, the photonic absorption layer 206, the first conduction layer 202A, the plasmonic layer 204, the second diode layer 208B, the second conduction layer 202B, the power collar 104, the interconnect traces 103, and the energy cell 106. One or more optional layers can be included, such as the third diode layer 208C, fourth diode layer 208D, etc. The fifth enhanced hybrid plasmonic photovoltaic collector cross-section 600E has a convex shape, where the photovoltaic collector is elongated toward an incident surface 231 of incident light 230, with a largest angle of curvature, α, at the edges of the photovoltaic collector. The functionality of the fifth enhanced hybrid plasma-sonic photovoltaic collector cross-section 600E includes one or more layers of the enhanced hybrid plasmonic photovoltaic cell cross-section 350 (FIG. 5B), as described supra with respect to FIG. 5B and FIGS. 6A-6D. Functional aspects of additional layers, which can include the rectifier bridge circuitry 220 and the power collar 104, are also described supra with respect to FIG. 5B and FIGS. 6A-6D.

As depicted in FIG. 6E, the energy cell 106 is situated adjacent the rectifier bridge circuitry 220 or the power collar 104 of the fifth enhanced hybrid plasmonic photovoltaic collector cross-section 600E. The energy cell 106 can be a battery (e.g., a Ii-ion polymer battery) or a capacitor capable of storing a charge and provides a low impedance path to the alternating current (e.g., IAc) thereby cancelling cyclical charges. The fifth enhanced hybrid plasmonic photovoltaic collector cross-section 600E has a convex shape, where the photovoltaic collector is elongated toward an incident surface 231 of incident light 230, with a largest angle of curvature, α, at the edges of the photovoltaic collector. Although not specifically shown in FIG. 6E, positive and negative terminals of energy cell 106 may be electrically coupled to one or more connection units 105 via interconnect traces, such that the positive terminal (anode) of cell 106 is connected to male pin connector 105A and the negative terminal (cathode) of cell 106 is connected to female socket connector 105B, at the edge of photovoltaic collector 100 corresponding to the fifth enhanced hybrid plasmonic photovoltaic collector cross-section 600E (FIGS. 1A, 12A-12D, and 13).

FIG. 6F depicts a sixth enhanced hybrid plasmonic photovoltaic collector cross-section 600F that is a variant of the first enhanced hybrid plasmonic photovoltaic collector cross-section 600A and includes aspects of the second enhanced hybrid plasmonic photovoltaic collector cross-section 600B and the fifth enhanced hybrid plasmonic photovoltaic collector cross-section 600E. The sixth enhanced hybrid plasmonic photovoltaic collector cross-section 600F includes a reflector layer 212 provided adjacent the third conduction layer 202C along a distal surface 232 of incident light 230 and a translucent layer 210 adjacent the second conduction layer 202B along incident surface 231 of incident light 230.

The translucent layer 210 and the reflector layer 212 sandwich one or more layers of the enhanced hybrid plasmonic photovoltaic cell cross-section 350 (FIG. 5B), such as the third conduction layer 202C, the third diode layer 208C, the photonic absorption layer 206, the first conduction layer 202A, the plasmonic layer 204, the second diode layer 208B, the second conduction layer 202B, the power collar 104, the interconnect traces 103, and the energy cell 106. One or more optional layers can be included, such as the third diode layer 208C, fourth diode layer 2080, etc. The sixth enhanced hybrid plasmonic photovoltaic collector cross-section 600F has a convex shape, where the photovoltaic collector is elongated toward an incident surface 231 of incident light 230, with a largest angle of curvature, α, at the edges of the photovoltaic collector. The functionality of the sixth enhanced hybrid plasmonic photovoltaic collector cross-section 600F includes one or more layers of the enhanced hybrid plasmonic photovoltaic cell cross-section 350, as described supra with respect to FIG. 5B and FIGS. 6A-6E. Functional aspects of additional layers, which can include the energy cell 106, the rectifier bridge circuitry 220, and the power collar 104, are also described supra with respect to FIG. 5B and FIGS. 6A-6E.

FIG. 6G depicts a seventh enhanced hybrid plasmonic photovoltaic collector cross-section 600G that is a variant of the first enhanced hybrid plasmonic photovoltaic collector cross-section 600A. The seventh enhanced hybrid plasmonic photovoltaic collector cross-section 600G includes a first translucent layer 210A provided adjacent the third conduction layer 202C along a distal surface 232 of incident light 230 and a second translucent layer 210B adjacent the second conduction layer 202B along incident surface 231 of incident light 230.

The first translucent layer 210A and the second translucent layer 210B sandwich one or more layers of the enhanced hybrid plasmonic photovoltaic cell cross-section 350 (FIG. 5B), such as the third conduction layer 202C, the third diode layer 208C, the photonic absorption layer 206, the first conduction layer 202A, the plasmonic layer 204, the second diode layer 208B, the second conduction layer 202B, the power collar 104, the interconnect traces 103, light emitting diodes (LEDs) 235, and the energy cell 106. One or more optional layers can be included, such as the third diode layer 208C, fourth diode layer 208D, etc. The seventh enhanced hybrid plasmonic photovoltaic collector cross-section 600G has a convex shape, where the photovoltaic collector is elongated toward an incident surface 231 of incident light 230, with a largest angle of curvature, α, at the edges of the photovoltaic collector. The functionality of the seventh enhanced hybrid plasmonic photovoltaic collector cross-section 600G includes one or more layers of the enhanced hybrid plasmonic photovoltaic cell cross-section 350, as described supra with respect to FIG. 5B and FIGS. 6A-6F. Functional aspects of additional layers, which can include the energy cell 106, the rectifier bridge circuitry 220, and the power collar 104, are also described supra with respect to FIG. 5B and FIGS. 6A-6F.

FIG. 6H depicts an eighth enhanced hybrid plasmonic photovoltaic collector cross-section 600H that is a variant of the first enhanced hybrid plasmonic photovoltaic collector cross-section 600A. The eighth enhanced hybrid plasmonic photovoltaic collector cross-section 600H includes a reflector layer 212 provided adjacent the third conduction layer 202c along a distal surface 232 of incident light 230 and a translucent layer 210 adjacent the second conduction layer 202B along an incident surface 231 of incident light 230.

The reflector layer 212 and the translucent layer 210 sandwich one or more layers of the enhanced hybrid plasmonic photovoltaic cell cross-section 350 (FIG. 5B), such as the third conduction layer 202C, the third diode layer 208C, the photonic absorption layer 206, the first conduction layer 202A, the plasmonic layer 204, the second diode layer 208B, the second conduction layer 202B, the power collar 104, the interconnect traces 103, LEDs 235, and the energy cell 106. One or more optional layers can be included, such as the third diode layer 208C, fourth diode layer 2080, etc. The eighth enhanced hybrid plasmonic photovoltaic collector cross-section 600H has a convex shape, where the photovoltaic collector is elongated toward an incident surface 231 of incident light 230, with a largest angle of curvature, α, at the edges of the photovoltaic collector. The functionality of the eighth enhanced hybrid plasmonic photovoltaic collector cross-section 600H includes one or more layers of the enhanced hybrid plasmonic photovoltaic cell cross-section 350, as described supra with respect to FIG. 5B and FIGS. 6A-6G. Functional aspects of additional layers, which can include the energy cell 106, the rectifier bridge circuitry 220, and the power collar 104, are also described supra with respect to FIG. 5B and FIGS. 6A-6G.

FIG. 6I depicts a ninth enhanced hybrid plasmonic photovoltaic collector cross-section 600I that is a variant of the first enhanced hybrid plasmonic photovoltaic collector cross-section 600A. The ninth enhanced hybrid plasmonic photovoltaic collector cross-section 600I includes the translucent layer 210 surrounding one or more layers of the enhanced hybrid plasmonic photovoltaic cell cross-section 350 (FIG. 5B), such as the third conduction layer 202C, the third diode layer 208C, the photonic absorption layer 206, the fourth diode layer 208D, the first conduction layer 202A, the first diode layer 208A, the plasmonic layer 204, the second diode layer 208B, the second conduction layer 202B, the power collar 104, and the interconnect traces 103. The ninth enhanced hybrid plasmonic photovoltaic collector cross-section 600I has a convex shape, where the photovoltaic collector is elongated toward an incident surface 231 of incident light 230, with a largest angle of curvature, α, at the edges of the photovoltaic collector. The functionality of the ninth enhanced hybrid plasmonic photovoltaic collector cross-section 600I includes one or more layers of the enhanced hybrid plasmonic photovoltaic cell cross-section 350, as described supra with respect to FIG. 5B and FIGS. 6A-6H. Functional aspects of additional layers, which can include the interconnect traces 103, the rectifier bridge circuitry 220, and the power collar 104, are also described supra with respect to FIG. 5B and FIGS. 6A-6H.

FIG. 6J depicts a tenth enhanced hybrid plasmonic photovoltaic collector cross-section 600J that is a variant of the first enhanced hybrid plasmonic photovoltaic collector cross-section 600A. The tenth enhanced hybrid plasmonic photovoltaic collector cross-section 600J includes the translucent layer 210 surrounding one or more layers of the enhanced hybrid plasmonic photovoltaic cell cross-section 350 (FIG. 5B), such as the third conduction layer 202C, the third diode layer 208C, the photonic absorption layer 206, the fourth diode layer 2080, the first conduction layer 202A, the first diode layer 208A, the plasmonic layer 204, the second diode layer 208B, the second conduction layer 202B, the power collar 104, the light-emitting diodes (LEDs) 235, and the interconnect traces 103. The tenth enhanced hybrid plasmonic photovoltaic collector cross-section 600J has a convex shape, where the photovoltaic collector is elongated toward an incident surface 231 of incident light 230, with a largest angle of curvature, α, at the edges of the photovoltaic collector. The functionality of the tenth enhanced hybrid plasmonic photovoltaic collector cross-section 600J includes one or more layers of the enhanced hybrid plasma-sonic photovoltaic cell cross-section 350, as described supra with respect to FIG. 5B and FIGS. 6A-6I. Functional aspects of additional layers, which can include the interconnect traces 103, the rectifier bridge circuitry 220, and the power collar 104, are also described supra with respect to FIG. 5B and FIGS. 6A-6I.

FIG. 6K depicts an eleventh enhanced hybrid plasmonic photovoltaic collector cross-section 600K that is a variant of the first enhanced hybrid plasmonic photovoltaic collector cross-section 600A. The eleventh enhanced hybrid plasmonic photovoltaic collector cross-section 600K includes a first translucent layer 210A and a second translucent layer 210B that sandwich one or more layers of the enhanced hybrid plasmonic photovoltaic cell cross-section 350 (FIG. 5B), such as the third conduction layer 202C, the third diode layer 208C, the photonic absorption layer 206, the fourth diode layer 208D, the first conduction layer 202A, the first diode layer 208A, the plasmonic layer 204, the second diode layer 208B, the second conduction layer 202B, the power collar 104, energy cell 106, the LEDs 235, and the interconnect traces 103. The eleventh enhanced hybrid plasmonic photovoltaic collector cross-section 600K has a convex shape, where the photovoltaic collector is elongated toward an incident surface 231 of incident light 230, with a largest angle of curvature, α, at the edges of the photovoltaic collector. The functionality of the eleventh enhanced hybrid plasmonic photovoltaic collector cross-section 600K includes one or more layers of the enhanced hybrid plasmonic photovoltaic cell cross-section 350, as described supra with respect to FIG. 5B and FIGS. 6A-6J. Functional aspects of additional layers, which can include the energy cell 106, the rectifier bridge circuitry 220, and the power collar 104, are also described supra with respect to FIG. 5B and FIGS. 6A-6J.

FIG. 6L depicts a twelfth enhanced hybrid plasmonic photovoltaic collector cross-section 600L that is a variant of the first enhanced hybrid plasmonic photovoltaic collector cross-section 600A. The twelfth enhanced hybrid plasmonic photovoltaic collector cross-section 600L includes a reflector layer 212 provided adjacent the third conduction layer 202C along a distal surface 232 of incident light 230 and a translucent layer 210 adjacent the second conduction layer 202B along an incident surface 231 of incident light 230.

The reflector layer 212 and the translucent layer 210 sandwich one or more layers of the enhanced hybrid plasmonic photovoltaic cell cross-section 350 (FIG. 5B), such as the third conduction layer 202C, the third diode layer 208C, the photonic absorption layer 206, the fourth diode layer 208D, the first conduction layer 202A, the first diode layer 208A, the plasmonic layer 204, the second diode layer 208B, the second conduction layer 202B, the power collar 104, energy cell 106, the light-emitting diodes (LEDs) 235, and the interconnect traces 103. The twelfth enhanced hybrid plasmonic photovoltaic collector cross-section 600L has a convex shape, where the photovoltaic collector is elongated toward an incident surface 231 of incident light 230, with a largest angle of curvature, α, at the edges of the photovoltaic collector. The functionality of the twelfth enhanced hybrid plasmonic photovoltaic collector cross-section 600L includes one or more layers of the enhanced hybrid plasmonic photovoltaic cell cross-section 350, as described supra with respect to FIG. 5B and FIGS. 6A-6K. Functional aspects of additional layers, which can include the energy cell 106, the rectifier bridge circuitry 220, and the power collar 104, are also described supra with respect to FIG. 5B and FIGS. 6A-6K.

FIG. 6M depicts a thirteenth enhanced hybrid plasmonic photovoltaic collector cross-section 600M that includes the translucent layer 210 that envelopes the first conduction layer 202A, the plasmonic layer 204, the second diode layer 208B, the second conduction layer 202B, the power collar 104, and the interconnect traces 103. The thirteenth enhanced hybrid plasmonic photovoltaic collector cross-section 600M has a convex shape, where the photovoltaic collector is elongated toward an incident surface 231 of incident light 230, with a largest angle of curvature, α, at the edges of the photovoltaic collector. The functionality of the thirteenth enhanced hybrid plasmonic photovoltaic collector cross-section 600M includes one or more layers of the enhanced hybrid plasmonic photovoltaic cell cross-section 350, as described supra with respect to FIG. 5B and FIGS. 6A-6L. Functional aspects of additional layers, which can include the interconnect traces 103, the rectifier bridge circuitry 220, and the power collar 104, are also described supra with respect to FIG. 5B and FIGS. 6A-6L.

In some configurations, the thirteenth enhanced hybrid plasmonic photovoltaic collector cross-section 600M includes a reflector layer 212 provided on a distal surface 232 of incident light 230. In such a configuration, the reflector layer 212 is configured to reflect incident light 230 back toward the plasmonic layer 204 to increase chances of absorption. The reflector layer 212 can be a metal layer, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

FIG. 6N depicts a fourteenth enhanced hybrid plasmonic photovoltaic collector cross-section 600N that includes the first translucent layer 210A and the second translucent layer 210B that sandwich one or more layers of the enhanced hybrid plasmonic photovoltaic cell cross-section 350 (FIG. 5B), such as the first conduction layer 202A, the plasmonic layer 204, the second diode layer 208B, the second conduction layer 202B, the power collar 104, the interconnect traces 103, and the energy cell 106. The fourteenth enhanced hybrid plasmonic photovoltaic collector cross-section 600N has a convex shape, where the photovoltaic collector is elongated toward an incident surface 231 of incident light 230, with a largest angle of curvature, α, at the edges of the photovoltaic collector. The functionality of the fourteenth enhanced hybrid plasmonic photovoltaic collector cross-section 600N includes one or more layers of the enhanced hybrid plasmonic photovoltaic cell cross-section 350, as described supra with respect to FIG. 5B and FIGS. 6A-6M. Functional aspects of additional layers, which can include the energy cell 106, the rectifier bridge circuitry 220, and the power collar 104, are also described supra with respect to FIG. 5B and FIGS. 6A-6M.

In some configurations, the fourteenth enhanced hybrid plasmonic photovoltaic collector cross-section 600N includes a reflector layer 212 provided on a distal surface 232 of incident light 230. In such a configuration, the reflector layer 212 is configured to reflect incident light 230 back toward the surface of plasmonic layer 204 to increase chances of absorption. The reflector layer 212 can be a metal layer, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

FIG. 6O depicts a fifteenth enhanced hybrid plasmonic photovoltaic collector cross-section 600O that includes the translucent layer 210 that envelopes the third conduction layer 202C, third diode layer 208C, first plasmonic layer 204A, first conduction layer 202A, second plasmonic layer 204B, the second diode layer 208B, the second conduction layer 202B, the power collar 104, and the interconnect traces 103. The fifteenth enhanced hybrid plasmonic photovoltaic collector cross-section 600O has a convex shape, where the photovoltaic collector is elongated toward an incident surface 231 of incident light 230, with a largest angle of curvature, α, at the edges of the photovoltaic collector. The functionality of the fifteenth enhanced hybrid plasmonic photovoltaic collector cross-section 600M includes one or more layers of the enhanced hybrid plasmonic photovoltaic cell cross-section 350, as described supra with respect to FIG. 5B and FIGS. 6A-6N. Functional aspects of additional layers, which can include the interconnect traces 103, the rectifier bridge circuitry 220, and the power collar 104, are also described supra with respect to FIG. 5B and FIGS. 6A-6N.

In some configurations, the fifteenth enhanced hybrid plasmonic photovoltaic collector cross-section 600O includes a reflector layer 212 provided on a distal surface 232 of incident light 230. In such a configuration, the reflector layer 212 is configured to reflect incident light 230 back toward plasmonic layers 204A and 204B to increase chances of absorption. The reflector layer 212 can be a metal layer, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

FIG. 6P depicts a sixteenth enhanced hybrid plasmonic photovoltaic collector cross-section 600P that includes the translucent layers 210A and 210B that envelope the third conduction layer 202C, third diode layer 208C, the first plasmonic layer 204A, the first conduction layer 202A, the second plasmonic layer 204B, the second diode layer 208B, the second conduction layer 202B, the power collar 104, the energy cell 106, and the interconnect traces 103. The sixteenth enhanced hybrid plasmonic photovoltaic collector cross-section 600P has a convex shape, where the photovoltaic collector is elongated toward an incident surface 231 of incident light 230, with a largest angle of curvature, α, at the edges of the photovoltaic collector. The functionality of the sixteenth enhanced hybrid plasmonic photovoltaic collector cross-section 600M includes one or more layers of the enhanced hybrid plasmonic photovoltaic cell cross-section 350, as described supra with respect to FIG. 5B and FIGS. 6A-6O. Functional aspects of additional layers, which can include the energy cell 106, the rectifier bridge circuitry 220, and the power collar 104, are also described supra with respect to FIG. 5B and FIGS. 6A-6O.

In some configurations, the sixteenth enhanced hybrid plasmonic photovoltaic collector cross-section 600P includes a reflector layer 212 provided on a distal surface 232 of incident light 230. In such a configuration, the reflector layer 212 is configured to reflect incident light 230 back toward plasmonic layers 204A and 204B to increase chances of absorption. The reflector layer 212 can be a metal layer, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

FIG. 6Q depicts a seventeenth enhanced hybrid plasmonic photovoltaic collector cross-section 600Q that includes the translucent layer 210 that envelopes the first conduction layer 202A, the photonic absorption layer 206, the second diode layer 208B, the second conduction layer 202B, the power collar 104, and the interconnect traces 103. The seventeenth enhanced hybrid plasmonic photovoltaic collector cross-section 600Q has a convex shape, where the photovoltaic collector is elongated toward an incident surface 231 of incident light 230, with a largest angle of curvature, α, at the edges of the photovoltaic collector. The functionality of the seventeenth enhanced hybrid plasmonic photovoltaic collector cross-section 600Q includes one or more layers of the enhanced hybrid plasmonic photovoltaic cell cross-section 350, as described supra with respect to FIG. 5B and FIGS. 6A-6P. Functional aspects of additional layers, which can include the interconnect traces 103, the rectifier bridge circuitry 220, and the power collar 104, are also described supra with respect to FIG. 5B and FIGS. 6A-6P.

In some configurations, the seventeenth enhanced hybrid plasmonic photovoltaic collector cross-section 600Q includes a reflector layer 212 provided on a distal surface 232 of incident light 230. In such a configuration, the reflector layer 212 is configured to reflect incident light 230 back toward photonic absorption layer 206 to increase chances of absorption. The reflector layer 212 can be a metal layer, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

FIG. 6R depicts a eighteenth enhanced hybrid plasmonic photovoltaic collector cross-section 600R that includes the translucent layer 210 that includes a first translucent layer 210A provided adjacent the first conduction layer 202A along a distal surface 232 of incident light 230 and a second translucent layer 210B adjacent the second conduction layer 202B along an incident surface 231 of incident light 230. The first translucent layer 210A and the second translucent layer 210B sandwich one or more layers of the enhanced hybrid plasmonic photovoltaic cell cross-section 350 (FIG. 5B), such as the first conduction layer 202A, the photonic absorption layer 206, the second diode layer 208B, the second conduction layer 202B, the power collar 104, the energy cell 106, and the interconnect traces 103. The eighteenth enhanced hybrid plasmonic photovoltaic collector cross-section 600R has a convex shape, where the photovoltaic collector is elongated toward an incident surface 231 of incident light 230, with a largest angle of curvature, α, at the edges of the photovoltaic collector. The functionality of the eighteenth enhanced hybrid plasmonic photovoltaic collector cross-section 600R includes one or more layers of the enhanced hybrid plasmonic photovoltaic cell cross-section 350, as described supra with respect to FIG. 5B and FIGS. 6A-6Q. Functional aspects of additional layers, which can include the interconnect traces 103, the rectifier bridge circuitry 220, and the power collar 104, are also described supra with respect to FIG. 5B and FIGS. 6A-6Q.

In some configurations, the eighteenth enhanced hybrid plasmonic photovoltaic collector cross-section 600R includes a reflector layer 212 provided on a distal surface 232 of incident light 230. In such a configuration, the reflector layer 212 is configured to reflect incident light 230 back toward the photonic absorption layer 206 to increase chances of absorption. The reflector layer 212 can be a metal layer, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

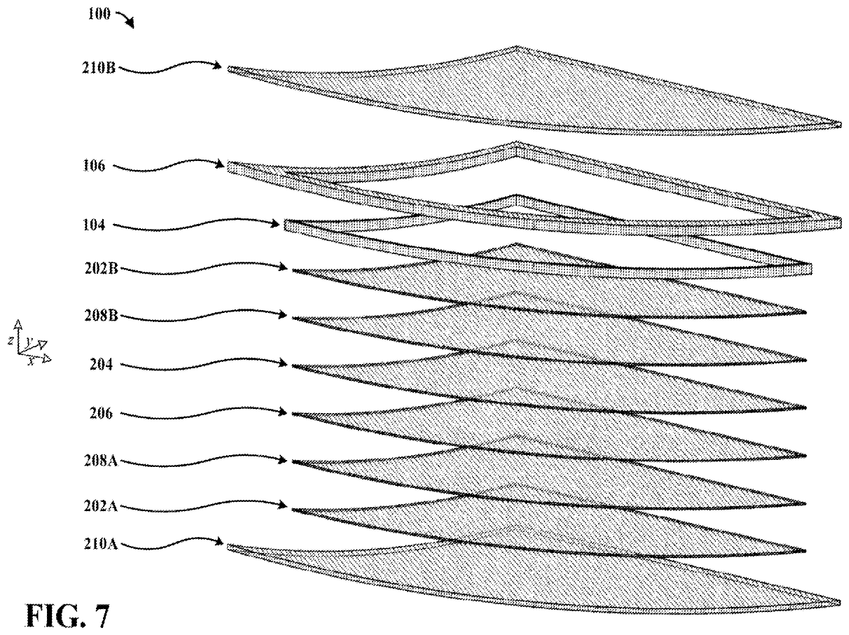

FIG. 7 illustrates an exploded view of exemplary plasmonic-based photovoltaic collector 100. The photovoltaic collector 100 includes a first translucent layer 210A, a first conduction layer 202A, a first diode layer 208A, a photonic absorption layer 206, a plasmonic layer 204, a second diode layer 208B, a second conduction layer 202B, a power collar 104, an energy cell 106, and a second translucent layer 210B. In this instance, the power collar 104 includes the rectifier bridge circuitry 220 to direct electrical power from the photonic absorption layer 206 and the plasmonic layer 204. Likewise, the energy cell 106 includes an anode and a cathode electrically coupled to the power collar 104 so as to store charge for later use. Although not shown in FIG. 7, photovoltaic collector 100 may further include one or more connection units 105 (FIGS. 1A, 12A-12D, and 13) to electrically couple power collar 104 and/or energy cell 106 of photovoltaic collector 100 to corresponding power collar 104 and/or energy cell 106 of one or more adjacent photovoltaic collectors.

FIG. 8 illustrates an ISO view of an exemplary hybrid plasmonic-based photovoltaic collector 100 with bracketing couplers 120. The photovoltaic collector 100 is a triangular shape and includes a microcontroller/processor 102 to regulate the power transfer from an energy cell 106 to an inverter or grid tie. The microcontroller/processor 102 includes one or more programmable input/output peripherals 1104 ((FIG. 11) e.g., voltage sensor situated at an anode and/or cathode of the energy cell 106, communication interface circuit to communicate with a power bridge or power inverter) to balance the load and facilitate power distribution to the electrical grid. The microcontroller/processor 102 is positioned at or near an apex of a triangle corner 122.

The bracketing coupler 120 is ‘I’ shaped so as to structurally interconnect with an edge of the photovoltaic collector 100. The bracketing coupler 120 extends along an edge length of the photovoltaic collector 100. In some examples, the bracketing coupler 120 is configured to electrically couple with the energy cell 106 so as to distribute power at the edges near an apex of a triangle corner 122. In some instances, the bracketing coupler 120 is configured with a power cable/coupler so as to transfer power from the energy cell 106 to an inverter or grid tie. In some examples, the bracketing coupler 120 is electrically insulated so as to prevent electrical power transfer from adjacent photovoltaic collectors 100. For example, bracketing couplers 120 are electrically insulated and situated at triangular apexes away from the microcontroller/processor 102. This configuration electrically isolates adjacent photovoltaic collectors 100 so that one or more photovoltaic collectors 100 can be disabled or disconnected without impeding the energy collection of the remaining photovoltaic collectors 100 in an array.

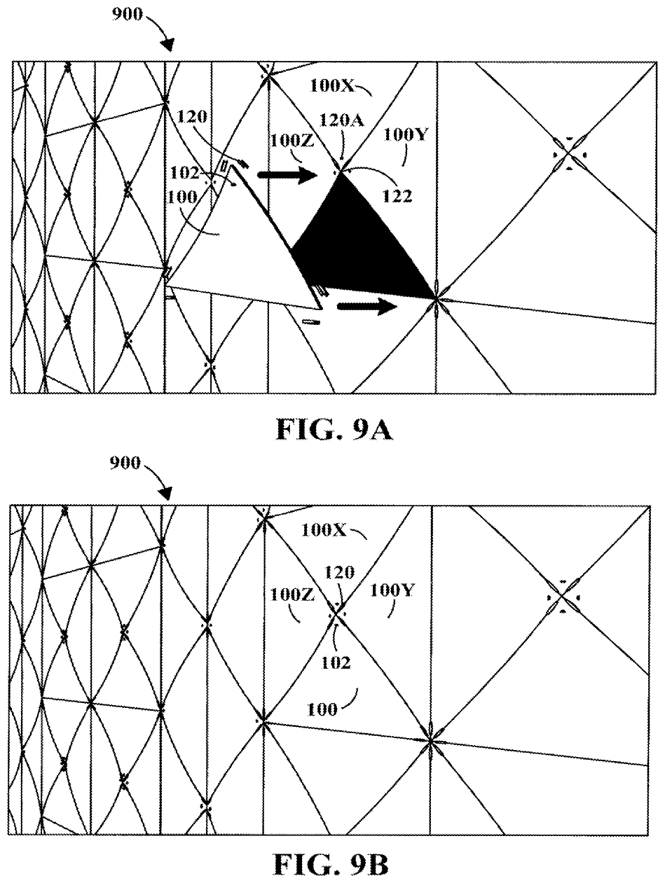

In some examples, the bracketing coupler 120 includes electrical switches so as to direct electrical power from one or more adjacent photovoltaic collectors. For example, an adjacent microcontroller/processor 102A (FIGS. 9A and 9B) can communicate with a microcontroller/processor 102 and indicate that an energy cell of the first adjacent photovoltaic cell 100X is not at full capacity. In turn, the microcontroller/processor 102A can (e.g., via one or more programmable input/output peripherals 1104 (FIG. 11)) throw a switch (e.g., relay, transistor, etc.) of the bracketing coupler 120 and direct power from the energy cell or generated from photonic absorption layer 206 (FIGS. 6A-6L, 6Q, and 6R) and/or plasonic layer 204 (FIGS. 6A-6P) of the photovoltaic collectors 100 to charge the energy cell of the first adjacent photovoltaic cell 100X. As explained previously, each photovoltaic collector 100 may include one or more connection units 105 (FIGS. 1A, 12A-12D, and 13) to electrically couple power collar 104 and/or energy cell 106 of photovoltaic collector 100 to corresponding power collar 104 and/or energy cell 106 of one or more adjacent photovoltaic collectors.

FIGS. 9A and 9B illustrate an array 900 of tessellated plasmonic-based collectors (e.g., 100, 100X, 100Y, 100Z). As depicted in FIG. 9A, the triangular photovoltaic collector 100 is configured to be positioned and in some instances electrically connected with a first adjacent triangular photovoltaic collector 100X, a second adjacent triangular photovoltaic collector 100Y, and a third adjacent triangular photovoltaic collector 100Z, via multiple connection units 105 disposed on each of the photovoltaic collectors 100, 100X, 100Y, 100Z to electrically couple and interlock and tessellate the collectors 100, 100X, 100Y, 100Z into an array. An apex of a triangle corner of adjacent triangular photovoltaic collectors 100 is positioned with the microcontroller/processors 102 situated in proximity with each other. The proximity microcontroller/processor 102 facilitates communication between the first adjacent triangular photovoltaic collector 100X the second adjacent triangular photovoltaic collector 100Y, and the third adjacent triangular photovoltaic collector 100Z.

FIG. 9B depicts the triangular photovoltaic collector 100 tessellated with the first adjacent triangular photovoltaic collector 100X, a second adjacent triangular photovoltaic collector 100Y, and a third adjacent triangular photovoltaic collector 100Z. It should be appreciated that the photovoltaic collector 100 can include various shapes. For example, a similar array can be tessellated with one or more of the plurality of photovoltaic collectors that have a triangular, a rectangular, a pentangular, a hexangular, an octangular shape, or other shape similar to the shapes depicted in FIG. 2.

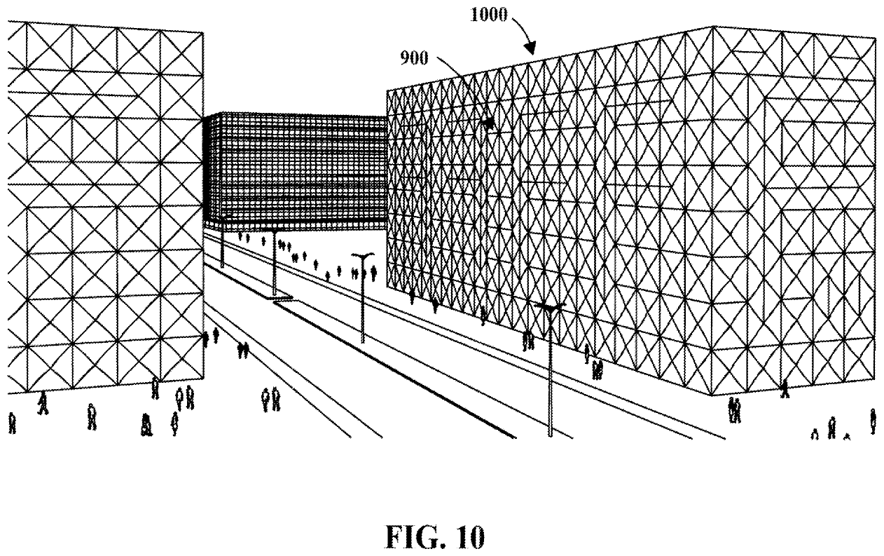

FIG. 10 illustrates one application of tessellated arrays 900, enveloping one or more buildings 1000. In this instance, the tessellated array 900 is a plurality of solar photovoltaic collectors (e.g., 100, 100X, 100Y, 100Z) that forms an additional exterior wall offset from an exterior surface of the building. As depicted in FIG. 10, the multiple triangular photovoltaic collectors (e.g., 100, 100X, 100Y, 100Z) form a covering (e.g., skin) around exterior wall of the building that envelopes at least a portion of the building. In some configurations, one or more of the triangular photovoltaic collectors (e.g., 100, 100X, 100Y, 100Z) are transparent so as to provide for viewing the features outside the building 900. In some examples, one or more of the triangular photovoltaic collectors (e.g., 100, 100X, 100Y, 100Z) are translucent so as to provide for sunlight to enter the building 900 while providing for privacy within the building 1000.

In some configurations, the tessellated array 900 is retrofitted outside the external wall/roof of an existing building 1000. In some instances, the tessellated array 900 includes mounting assembly (e.g., bracketing couplers 120, connection units 105, scaffolding, etc.) configured to bracket, interconnect, and interlock the plurality of solar photovoltaic collectors of building 1000. In some examples, the covering of the tessellated array 900 is integrated into the existing wall/roof of a building 1000. For example, one or more of the plurality of solar photovoltaic collectors (e.g., 100, 100X, 100Y, 100Z) is a window or a panel that separates interior from exterior of the building 1000.

FIG. 11 illustrates a conceptual data flow diagram illustrating the data flow between different hardware of a hybrid plasmonic-based photovoltaic collector 100 that implements a plasmonic generator 205 and a photonic generator 207. The plasma-sonic generator 205 generally describes one or more plasma-sonic layers (204A, 204B, . . . 204N, etc.) that facilitates capturing the oscillation of charged carriers (e.g., electrons, holes, etc.) of the nanoparticles in the plasmonic layer 204 at the second conduction layer 202B. The plasma-sonic generator 205 can include a first plasma-sonic layer 204A electrically coupled to a first conductor layer 202A, as depicted in FIGS. 6O and 6P. The plasma-sonic generator 205 can also include a second plasma-sonic layer 204B parallel to the first plasma-sonic layer 204A and electrically coupled to a second conductor layer 202B, as depicted in FIGS. 6O and 6P. It is contemplated that the three or more plasma-sonic layers (e.g., Nth plasma-sonic layer) can be provided in the photovoltaic collector 100.

The photonic generator 207 generally describes one or more photonic absorption layers (206A, 206B, . . . 206N, etc.) that generate electron-hole pairs from incident light longer than specific wavelengths, which in turn induces a direct electric current. The photonic generator 207 can include a first photonic absorption layer 206A in parallel with the plasma-sonic generator 205. For example, FIGS. 5A, 5B, and 6A-6L depict the photonic absorption layer 206 stacked in parallel with the plasmonic layer 204. The photonic generator 207 can also include a second photonic absorption layer 206B parallel to the first photonic absorption layer 206A, analogous to the parallel configuration of the first plasma-sonic layer 204A and the second plasma-sonic layer 204B depicted in FIGS. 6O and 6P. It is contemplated that the two or more photonic absorption layer layers (e.g., Nth photonic absorption layer 206) can be provided in the photovoltaic collector 100.

The power collar 104 is electrically coupled to one or more programmable input/output peripherals 1104 from the microcontroller/processor 102. In some configuration, the power collar 104 includes the rectifier bridge circuitry 220, such as a half-wave bridge rectifier 222 or a full-wave rectifier bridge. The half-wave bridge rectifier 222 includes one or more diodes interconnected so as to covert a AC power signal 410 (depicted at test probe A of FIG. 4B) from the plasmonic photovoltaic cell cross-section 200 to a pulsed DC power signal 412 (depicted at test probe B of FIG. 4B) to a power collar 104 at a periphery of the photovoltaic collector 100. As discussed supra, power collar 104 may be electrically coupled to connection unit 105 at the edge of the photovoltaic collector 100 to physical interlock and electrically interconnect photovoltaic collector 100 to adjacent collectors. As discussed supra, the microcontroller/processor 102 includes one or more programmable input/output peripherals 1104 (e.g, voltage sensor situated at an anode and/or cathode of the energy cell 106, communication interface circuit to communicate with a power bridge or power inverter). The input/output peripherals 1104 are configured to sense load parameters from the power collar 104, an energy cell 106, a power bridge 1120, and an inverter 1130 and store each load parameter to memory 1102.

In one configuration, the power collar 104 is configured to provide DC power from the plasma-sonic generator 205 and/or the photonic generator 207 to an inverter 1130. In such a configuration the DC power generated from the plasma-sonic generator 205 and/or the photonic generator 207 is converted to AC power suitable for off-grid application. As depicted in FIG. 11, the inverter 1130 can further provide AC power to a grid tie 1140 that is configured to provide AC power suitable for the power grid 1150. In some examples, the grid tie 1140 includes safety features to cease power transfer and electrifying the grid when an interrupt of instantaneous power (e.g., voltage, current) of the grid 1150 is sensed. For example, in some instances, the grid tie 1140 includes a disconnect/interrupt 1142 configured to sever power to the grid in the event of a detected disruption of instantaneous power (e.g., voltage, current) from the grid 1150.

In one optional configuration, the power collar 104 is configured to provide DC power to an energy cell 106. For example, the energy cell 106 provides a reservoir of charge carriers (e.g., electrons, holes, etc.) that lessens the variation in the rectified pulsed DC power signal 412 (depicted at test probe B of FIG. 4B) from the rectifier bridge circuitry 220. In turn, the DC power provided to the inverter 1130 is conditioned (e.g., smoothed), which can facilitate conversion from DC power to AC power suitable for the off-grid and on-grid applications.

In one optional configuration, the power collar 104 and/or the energy cell 106 are configured to provide DC power to a power bridge 1120. The power bridge 1120 is configured to balance the impedance between the power collar 104 and/or the energy cell 106 and inverter 1130 so as to optimize power transfer. In some examples, the power bridge 1120 retrieves the load parameters from the memory 1102 of the microcontroller/processor 102 and adjusts impedance of the power bridge 1120 to reduce signal reflections from the inverter 1130. In some examples, the power bridge 1120 is electrically coupled to the inverter 1130.

In some examples, the power bridge 1120 is a power transfer circuit affixed to the solar photovoltaic collector 100 and electrically coupled to the power collar 104 (e.g., at a first electrode and a second electrode). For example, the power bridge 1120 can include the microcontroller/processor 102 and the input/output peripherals 1104 to sense instantaneous power of an electrical power grid 1150, sense instantaneous power generated from the photovoltaic collector 100, and sweep power generated from the photovoltaic collector 100 to the electrical power grid 1150. In some instances, the power bridge 1120 includes wireless transfer circuitry to transmit electrical energy from the power bridge 1120 to the inverter 1130 using time-varying electric, magnetic, or electromagnetic fields.

According to a first embodiment, a photovoltaic cell, comprises: a first conduction layer; a second conduction layer; a photonic absorption layer electrically coupled to the first conduction layer, the photonic absorption layer is tuned to absorb incident light at a first wavelength of the incident light to generate a first electric current along the first conduction layer; and a plasma-sonic layer electrically coupled to the photonic absorption layer and the second conduction layer, the plasma-sonic layer includes nanoparticles, the nanoparticles are tuned to a second wavelength of the incident light that induces electrons to oscillate at a surface of the nanoparticles.

In another embodiment, the second conduction layer is configured to capture the oscillating electrons along the surface of the nanoparticles to generate a second electric current. In another embodiment, the first electric current is a direct current and the second electric current is an alternating current. In another embodiment, the first conduction layer is electrically coupled to the second conduction layer. In another embodiment, the photovoltaic cell according to the first embodiment further comprises a rectifier bridge configured to provide a same polarity of output with respect to reference ground for any polarity at a first input or second input, wherein the first input is electrically coupled to the second conduction layer and the second input is electrically coupled to the plasma-sonic layer. In another embodiment, the rectifier bridge is a full-wave rectifier or a half-wave rectifier. In another embodiment, the photovoltaic cell according to the fifth aspect further comprises an energy cell electrically coupled across the output of the rectifier bridge and the reference ground. In another embodiment, the rectifier bridge includes a diode reverse bias across the plasma-sonic layer and the energy cell. In another embodiment, the energy cell is a nickel cadmium (NiCd) battery, nickel-metal hydride (NiMH) battery, lithium ion (Ii-on) battery, or a lithium polymer battery. In another embodiment, the energy cell is a supercapacitor, an electrolytic capacitor, a ceramic capacitor, or a film capacitor. In another embodiment, the rectifier bridge includes a first diode layer electrically coupled in reverse bias between the first conduction layer and the photonic absorption layer. In another embodiment, the rectifier bridge includes a second diode layer electrically coupled in reverse bias between the second conduction layer and the plasma-sonic layer.

In another embodiment, the photovoltaic cell according to the first embodiment further comprises a substrate configured to hermetically seal the photonic absorption layer, the plasma-sonic layer, and the second conduction layer. In another embodiment, one or both of the first conduction layer and the second conduction layer include graphene. In another embodiment, the graphene is p-doped or n-doped. In another embodiment, capturing the oscillating electrons along the surface of the nanoparticles causes a temperature of the second conduction layer to decrease. In another embodiment, one or both of the first conductor layer and the second conductor layer includes conductive nanowires.

In another embodiment, the photovoltaic cell according to the first embodiment further comprises a power gap layer electrically coupled to one or both of the first conductor layer and the second conductor layer with the conductive nanowires. In another embodiment, the second wavelength of the incident light is a resonance wavelength of the oscillating electrons. In another embodiment, the first wavelength of the incident light or the second wavelength of the incident light is longer than 700 nanometers. In another embodiment, the first wavelength of the incident light is longer than the second wavelength of the incident light. In another embodiment, the first wavelength of the incident light is shorter than the second wavelength of the incident light. In another embodiment, the plasma-sonic layer is an electrical insulator. In another embodiment, the plasma-sonic layer is a dielectric with a complex dielectric constant. In another embodiment, the plasma-sonic layer is a polymer or a ceramic. In another embodiment, the plasma-sonic layer is a polycarbonate. In another embodiment, the nanoparticles are homogenously suspended in the plasma-sonic layer. In another embodiment, the nanoparticles have a conical, rectangular, bi-pyramidal, tetrahedral, cubical, octahedral, cylindrical, ellipsoidal, or spherical shape. In another embodiment, the nanoparticles are electrically insulating or electrically semiconducting. In another embodiment, the first wavelength is proportional to sizes of quantum dots in the photonic absorption layer. In another embodiment, the photonic absorption layer includes light scattering particles. In another embodiment, the first conduction layer, the second conduction layer, the plasma-sonic layer, and the photonic absorption layer are translucent or transparent to the incident light within the visible spectrum at a zero degree incident angle. In another embodiment, a combination of the first conduction layer, the second conduction layer, the plasma-sonic layer, and the photonic absorption layer has a transmittance of light within the visible spectrum greater than 0.76 at a zero degree incident angle.

In another embodiment, the photovoltaic cell according to the first embodiment further comprises a reflector provided on a distal surface of the photovoltaic cell opposite a surface of incident light, wherein the reflector is configured to reflect incident light back towards the surface of incident light. In another embodiment, the photovoltaic cell is flat or planar. In another embodiment, the photovoltaic cell is non-planar along a light incident surface. In another embodiment, the photovoltaic cell is curved along a light incident surface at an arc angle between 0 to 23.5 degrees. In another embodiment, the photovoltaic cell has a triangular, rectangular, pentangular, hexangular, elliptical, or circular shape.

In another embodiment, a solar photovoltaic collector comprises: a photovoltaic cell of the first embodiment; a first electrode electrically coupled to the first conduction layer, and a second electrode electrically coupled to the plasma-sonic layer and the photonic absorption layer, wherein the first electrode is electrically isolated from the second electrode. In another embodiment, the first electrode and the second electrode are situated around peripheral surfaces of the solar photovoltaic collector.

In another embodiment, the solar photovoltaic collector of the other embodiment further comprises: a power transfer circuit affixed to the photovoltaic collector and electrically coupled to the first electrode and the second electrode, wherein the power transfer circuit is configured to: sense instantaneous power of an electrical power grid, sense instantaneous power generated from the photovoltaic collector, and sweep power generated from the photovoltaic collector to the electrical power grid. In another embodiment, the power transfer circuit includes circuity to transfer the power wirelessly to the electrical power grid. In another embodiment, a solar photovoltaic collector array comprises: a plurality of solar photovoltaic collectors of the other embodiment, configured to tessellate with each other. In another embodiment, one or more of the plurality of photovoltaic collector has a triangular, rectangular, pentangular, hexangular, or octangular shape. In another embodiment, the solar photovoltaic collector array of the other embodiment further comprises a mounting assembly configured to bracket the plurality of solar photovoltaic collectors of a building. In another embodiment, one or more of the plurality of solar photovoltaic collectors is a window or a panel that separates interior from exterior of the building. In another embodiment, the plurality of solar photovoltaic collectors forms an additional exterior wall offset from an exterior surface of the building. In another embodiment, the additional exterior wall envelopes a portion of the building.

It is understood that the specific order or hierarchy of blocks in the processes/flowcharts disclosed is an illustration of exemplary approaches. Based upon design preferences, it is understood that the specific order or hierarchy of blocks in the processes/flowcharts can be rearranged. Further, some blocks can be combined or omitted. The accompanying method claims present elements of the various blocks in a sample order and are not meant to be limited to the specific order or hierarchy presented.

The previous description is provided to enable any person skilled in the art to practice the various examples described herein. Various modifications to these examples will be readily apparent to those skilled in the art, and the generic principles defined herein can be applied to other examples. Thus, the claims are not intended to be limited to the examples shown herein, but are to be accorded the full scope consistent with the language of the claims, wherein reference to an element in the singular is not intended to mean “one and only one,” unless specifically so stated, but rather “one or more.” The word “exemplary” is used herein to mean “serving as an example, instance, or illustration.” Any example described herein as “exemplary” is not necessarily to be construed as preferred or advantageous over other examples. Unless specifically stated otherwise, the term “some” refers to one or more. Combinations, such as “at least one of A, B, or C;” “one or more of A, B, or C;” “at least one of A, B, and C;” “one or more of A, B, and C;” and “A, B, C; or any combination thereof” include any combination of A, B, and/or C, and can include multiples of A, multiples of B, or multiples of C. Specifically, combinations, such as “at least one of A, B, or C,” “one or more of A, B, or C,” “at least one of A, B, and C,” “one or more of A, B, and C,” and “A, B, C, or any combination thereof” can be A only, B only, C only, A and B, A and C, B and C, or A and B and C, where any such combinations can contain one or more member or members of A, B, or C. All structural and functional equivalents to the elements of the various examples described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like cannot be a substitute for the word “means.” As such, no claim element is to be construed under 35 U.S.0 § 112(f) unless the element is expressly recited using the phrase “means for.”

What is claimed is:

1. A photovoltaic collector, comprising:
a photovoltaic cell configured to absorb incident light and generate electric current;
a power collar disposed along a periphery of the photovoltaic cell, the power collar electrically coupled to at least one conduction layer of the photovoltaic cell; and
a connection unit electrically connected to the power collar, the connection unit including:
a first connector electrically connected to a positive terminal of the power collar; and
a second connector electrically connected to a negative terminal of the power collar;
wherein the first and second connectors are disposed at an outer peripheral edge of the photovoltaic collector, and
wherein the first and second connectors are configured to interconnect the photovoltaic collector with a first adjacent photovoltaic collector.

2. The photovoltaic collector according to claim 1, further comprising an energy cell disposed along the periphery of the photovoltaic cell, and wherein the power collar is electrically connected to the energy cell and is configured to direct charged carriers to the energy cell.

3. The photovoltaic collector according to claim 2, wherein connection unit is electrically connected to the energy cell such that the first connector is electrically coupled to an anode of the energy cell and the second connector is electrically connected to a cathode of the energy cell.

4. The photovoltaic collector according to claim 1, wherein the first connector is a male pin connector and the second connector is a female socket connector, and
wherein the first and second connectors are disposed at the outer peripheral edge of the photovoltaic collector such that the male pin connector is electrically connectable with a corresponding female socket connector of the first adjacent photovoltaic collector, and the female socket connector is electrically connectable with a corresponding male pin connector of the first adjacent photovoltaic collector.

5. The photovoltaic collector according to claim 4, wherein the male pin connector is a flat or round pin connector, and the female socket connector is a flat or round receptacle connector.

6. The photovoltaic collector according to claim 1, wherein the photovoltaic cell is a triangular photovoltaic cell, and wherein the first and second connectors are disposed along a first edge of the triangular photovoltaic cell along an outer peripheral surface.

7. The photovoltaic collector according to claim 6, wherein the first and second connectors disposed along the first edge of the triangular photovoltaic cell are positioned adjacent to each other proximal to a first vertex of the first edge of the triangular photovoltaic cell.

8. The photovoltaic collector according to claim 6, wherein the first and second connectors disposed along the first edge of the triangular photovoltaic cell are positioned distal from each other such that the first connector is proximal to one vertex of the first edge of the triangular photovoltaic cell and the second connector is proximal to the other vertex of the first edge of the triangular photovoltaic cell.

9. The photovoltaic collector according to claim 6, further comprising:
a second connection unit electrically connected to the power collar, and including first and second connectors respectively electrically connected to the positive and negative terminals of the power collar; and
a third connection unit electrically connected to the power collar, and including first and second connectors respectively electrically connected to the positive and negative terminals of the power collar.

10. The photovoltaic collector according to claim 9, wherein the first and second connectors of the second connection unit are disposed along a second edge of the triangular photovoltaic cell along the outer peripheral surface, and the first and second connectors of the third connection unit are disposed along a third edge of the triangular photovoltaic cell along the outer peripheral surface.

11. The photovoltaic collector according to claim 10, wherein for each of the second and third connection units, the first and second connectors are disposed along a corresponding edge of the triangular photovoltaic cell so as to be positioned adjacent to each other proximal to a corresponding vertex of the triangular photovoltaic cell.

12. The photovoltaic collector according to claim 10, wherein for each of the second and third connection units, the first and second connectors are disposed along a corresponding edge of the triangular photovoltaic cell so as to be positioned distal from each other and such that the first connector is proximal to one vertex of the corresponding edge of the triangular photovoltaic cell and the second connector is proximal to the other vertex of the corresponding edge of the triangular photovoltaic cell.

13. The photovoltaic collector according to claim 10, wherein the first and second connectors of the second connection unit are configured to electrically connect and interlock the photovoltaic collector with a second adjacent photovoltaic collector, and wherein the first and second connectors of the third connection unit are configured to electrically connect and interlock the photovoltaic collector with a third adjacent photovoltaic collector.

14. The photovoltaic collector according to claim 1, wherein the photovoltaic cell is one of a rectangular photovoltaic cell, a pentangular photovoltaic cell, a hexangular photovoltaic cell, an elliptical photovoltaic cell, and a circular photovoltaic cell.

15. The photovoltaic collector according to claim 1, further comprising a second connection unit electrically connected to the power collar and including first and second connectors respectively electrically connected to the positive and negative terminals of the power collar.

16. The photovoltaic collector according to claim 1, wherein the first connector is electrically connected to the positive terminal of the power collar via a first interconnect trace and the second connector is electrically connected to the negative terminal of the power collar via a second interconnect trace.

17. The photovoltaic collector according to claim 16, wherein the first and second interconnect traces are embedded so as to be hermetically sealed within one or more protective layers of the photovoltaic collector, and wherein the first and second interconnect traces provide electrical conduits from the positive terminal and the negative terminal of the power collar to the first and second connectors, respectively, at the outer peripheral edge of the photovoltaic collector.

18. A photovoltaic collector array, comprising:
a plurality of photovoltaic collectors, each photovoltaic collector including:
a photovoltaic cell configured to absorb incident light and generate electric current;
a power collar disposed along a periphery of the photovoltaic cell; and
a plurality of connection units electrically connected to the power collar, wherein each connection unit is disposed at an outer peripheral edge of the photovoltaic collector, and is configured to electrically interconnect with an adjacent one of the plurality of photovoltaic collectors, and
wherein the plurality of photovoltaic collectors tessellate by interconnecting with each other via the plurality of connection units of the plurality of photovoltaic collectors.

19. The photovoltaic collector array according to claim 18, wherein each of the plurality of photovoltaic collectors is one of a triangular photovoltaic collector, a rectangular photovoltaic collector, a pentangular photovoltaic collector, a hexangular photovoltaic collector, an elliptical photovoltaic collector, and a circular photovoltaic collector.

20. The photovoltaic collector array according to claim 18, wherein the plurality of tessellating photovoltaic collectors are electrically connected to and interlocked with each other via only the plurality of connection units of the plurality of photovoltaic collectors, without requiring additional cable wires.

21. A photovoltaic collector comprising:
a photovoltaic cell including:
a first conduction layer;
a second conduction layer; and
a photovoltaic layer configured to absorb incident light and generate electric current, wherein the photovoltaic layer is electrically connected to the first conduction layer on a first side of the photovoltaic layer and to the second conduction layer on a second side opposite the first side;
wherein the first conduction layer is an ultrastatic conducting layer.

22. The photovoltaic collector according to claim 21, wherein the ultrastatic conducting layer is made using ultrasonic spray technology.

23. The photovoltaic collector according to claim 22, wherein the ultrastatic conducting layer is transparent or translucent coating.

24. The photovoltaic collector according to claim 22, wherein the ultrastatic conducting layer includes silver nanowires.

25. The photovoltaic collector according to claim 22, wherein the ultrastatic conducting layer includes graphene.

26. The photovoltaic collector according to claim 22, wherein a thickness of the ultrastatic conducting layer is approximately 200 nanometers.

27. The photovoltaic collector according to claim 21, wherein the second conduction layer is another ultrastatic conducting layer made using ultrasonic spray technology.

28. The photovoltaic collector according to claim 21, wherein the photovoltaic layer is a plasmonic layer that includes polymer dispersed with nanoparticles, wherein the nanoparticles are tuned to a predetermined wavelength of incident light that induces electrons to oscillate at a surface of the nanoparticles, and
wherein the first and second conduction layers are configured to capture the oscillating electrons along the surface of the nanoparticles to generate an alternating current.

29. The photovoltaic collector according to claim 21, wherein the photovoltaic layer is a photonic absorption layer that is tuned to absorb incident light to generate a direct current along the first or second conduction layer.

30. The photovoltaic collector according to claim 21, wherein the second side of the photovoltaic layer is an incident surface side from where incident light enters the photovoltaic collector, and wherein the first side of the photovoltaic layer is a distal surface side that is opposite to the incident surface side.

31. The photovoltaic collector according to claim 30, wherein the photovoltaic cell is a plasmonic photovoltaic cell, and the photovoltaic layer is a plasmonic layer that includes polymer dispersed with nanoparticles,
wherein the nanoparticles are tuned to a predetermined wavelength of incident light that induces electrons to oscillate at a surface of the nanoparticles, and wherein the first and second conduction layers are configured to capture the oscillating electrons along the surface of the nanoparticles to generate an alternating current, and
wherein the photovoltaic collector further comprises:
a photonic photovoltaic cell including:
a third conduction layer; and
a photonic absorption layer that is electrically connected to the first conduction layer on the incident surface side and to the third conduction layer on the distal surface side,
wherein the third conduction layer is another ultrastatic conducting layer.

32. The photovoltaic collector according to claim 31, wherein the photonic absorption layer is tuned to absorb the incident light to generate a direct current along the first or third conduction layer.

33. The photovoltaic collector according to claim 31, wherein the second conduction layer is made of a conductive material or a semimetal material, wherein the second conduction layer is not made the ultrasonic spray technology, and
wherein the first and third conduction layers are made of conductive silver nanowires, the first and third conduction layers being made with the ultrasonic spray technology.

34. A photovoltaic cell including:
a first conduction layer;
a second conduction layer; and
a photovoltaic layer configured to absorb incident light and generate electric current, wherein the photovoltaic layer is electrically connected to the second conduction layer on an incident surface side of the photovoltaic layer, the incident surface side being a side from where incident light enters the photovoltaic layer, and wherein the photovoltaic layer is further electrically connected to the first conduction layer on a distal surface side of the photovoltaic layer, the distal surface side being opposite to the incident surface side,
wherein the first conduction layer is an ultrastatic conducting layer, said ultrastatic conducting layer being made by ultrasonic spray technology.

35. The photovoltaic cell according to claim 34, wherein the ultrastatic conducting layer: (i) is transparent or translucent, (ii) includes at least one of silver nanowires and graphene, and (iii) has a thickness of approximately 200 nanometers.

36. The photovoltaic cell according to claim 34, wherein the second conduction layer is a transparent conducting layer made of a conducting or semimetal material, the second conduction layer being not made by the ultrasonic spray technology.

37. The photovoltaic cell according to claim 34, further comprising a first diode layer sandwiched between the first conduction layer and the photovoltaic layer, and a second diode layer sandwiched between the photovoltaic layer and the second conduction layer.

38. The photovoltaic cell according to claim 34, wherein the photovoltaic layer is a polymer layer with nanoparticles dispersed therein, wherein the polymer layer generates alternating current from the incident light.

39. The photovoltaic cell according to claim 34, wherein the photovoltaic layer is a semiconductor layer that implements quantum dots and that is configured to generate direct current from the incident light.

40. The photovoltaic cell according to claim 34, further comprising:
a power collar connected to the first and second conduction layers to draw electric current based on the incident light being absorbed by the photovoltaic layer; and
an energy cell being electrically coupled to the power collar, the energy cell configured to store the electric current generated by the photovoltaic cell.

41. The photovoltaic cell according to claim 40, further comprising a plurality of connection units, each connection unit including a male pin connector and a female socket connector, the plurality of connection units being disposed along on an outer peripheral edge of the photovoltaic cell,
wherein each connection unit is in electric connection with the power collar and the energy cell, and
wherein each connection unit is adapted to connect with an adjacent connection unit of an adjacent photovoltaic cell to tessellate and electrically interconnect and interlock the photovoltaic cell with a plurality of adjacent photovoltaic cells without requiring additional cable wires.
